(19) United States
(12) Patent Application Publication
(10) Pub. No.: US 2025/0285932 A1
(43) Pub. Date: Sep. 11, 2025

(54) SEMICONDUCTOR DEVICE AND ELECTRIC POWER CONVERSION UNIT

(71) Applicant: Rohm Co., Ltd., Kyoto-shi (JP)

(72) Inventor: Masashi HAYASHIGUCHI, Kyoto-shi (JP)

(21) Appl. No.: 19/214,644

(22) Filed: May 21, 2025

Related U.S. Application Data
(63) Continuation of application No. PCT/JP2023/041077, filed on Nov. 15, 2023.

(30) Foreign Application Priority Data
Nov. 28, 2022 (JP) 2022-188959

(51) Int. Cl. H01L 23/367; H01L 23/00; H01L 23/13; H01L 23/31; H01L 23/373; H01L 23/473; H01L 23/498; H01L 23/538; H01L 25/07; H10D 80/20

(52) U.S. Cl. CPC H01L 23/3677; H01L 23/13; H01L 23/3736; H01L 23/473; H01L 23/5383; H01L 23/5385; H01L 23/3121; H01L 23/3735; H01L 23/49811; H01L 24/37; H01L 24/40; H01L 24/41; H01L 24/48; H01L 24/73; H01L 25/072; H01L 2224/37147; H01L 2224/40155; H01L 2224/4103; H01L 2224/41051; H01L 2224/48155; H01L 2224/73221; H01L 2924/13091; H10D 80/251

(57) ABSTRACT

The semiconductor device includes a semiconductor element, a substrate supporting the semiconductor element, a sealing resin covering the semiconductor element and a part of the substrate, and a heat dissipation member. The substrate includes an obverse surface facing a first side in a thickness direction, and a reverse surface facing a second side in the thickness direction and exposed from the sealing resin. The semiconductor element is mounted on the obverse surface. The heat dissipation member is disposed on the substrate on the second side in the thickness direction. The heat dissipation member includes first bases located on the first side in the thickness direction, and first upright portions extending from the first bases to the second side in the thickness direction. The substrate includes first recesses recessed from the reverse surface to the first side in the thickness direction. The first bases are housed in the first recesses.

### TECHNICAL FIELD

The present disclosure relates to a semiconductor device and an electric power conversion unit.

### BACKGROUND ART

Semiconductor devices provided with power switching elements, such as metal oxide semiconductor field effect transistors (MOSFETs) and insulated gate bipolar transistors (IGBTs), have been conventionally known. Such semiconductor devices are mounted in various electronic devices, ranging from industrial devices to home appliances and information terminals, or even to vehicle-mount devices. JP-A-2021-190505 discloses a conventional semiconductor device (power module). The semiconductor device disclosed in JP-A-2021-190505 includes a semiconductor element and a support substrate. The semiconductor element is an IGBT made of silicon (Si), for example. The support substrate supports the semiconductor element. The support substrate includes an insulating base and conductor layers stacked on the respective surfaces of the base. The base is made of ceramic, for example. Each of the conductor layers is made of copper (Cu), for example, and the semiconductor element is bonded to one of the conductor layers. The semiconductor element is covered with a sealing resin, for example.

### BRIEF DESCRIPTION OF THE DRAWINGS

FIG. 1 is a perspective view showing a semiconductor device according to a first embodiment of the present disclosure.

FIG. 2 is a partial perspective view showing the semiconductor device according to the first embodiment of the present disclosure.

FIG. 3 is a partial perspective view showing the semiconductor device according to the first embodiment of the present disclosure.

FIG. 4 is a plan view showing the semiconductor device according to the first embodiment of the present disclosure.

FIG. 5 is a partial plan view showing the semiconductor device according to the first embodiment of the present disclosure.

FIG. 6 is a partial side view showing the semiconductor device according to the first embodiment of the present disclosure.

FIG. 7 is a partially enlarged plan view showing the semiconductor device according to the first embodiment of the present disclosure.

FIG. 8 is a partial plan view showing the semiconductor device according to the first embodiment of the present disclosure.

FIG. 9 is a partial plan view showing the semiconductor device according to the first embodiment of the present disclosure.

FIG. 10 is a side view showing the semiconductor device according to the first embodiment of the present disclosure.

FIG. 11 is a bottom view showing the semiconductor device according to the first embodiment of the present disclosure.

FIG. 12 is a partial bottom view showing the semiconductor device according to the first embodiment of the present disclosure.

FIG. 13 is a cross-sectional view along line XIII-XIII in FIG. 5.

FIG. 14 is a cross-sectional view along line XIV-XIV in FIG. 5.

FIG. 15 is a partially enlarged cross-sectional view showing the semiconductor device according to the first embodiment of the present disclosure.

FIG. 16 is a partially enlarged cross-sectional view showing the semiconductor device according to the first embodiment of the present disclosure.

FIG. 17 is a cross-sectional view along line XVII-XVII in FIG. 5.

FIG. 18 is a cross-sectional view along line XVIII-XVIII in FIG. 5.

FIG. 19 is a cross-sectional view along line XIX-XIX in FIG. 5.

FIG. 20 is a cross-sectional view along line XX-XX in FIG. 5.

FIG. 21 is a cross-sectional view along line XXI-XXI in FIG. 5.

FIG. 22 is a partially enlarged cross-sectional view along line XXII-XXII in FIG. 11.

FIG. 23 is a cross-sectional view showing an electric power conversion unit according to the first embodiment of the present disclosure.

FIG. 24 is a cross-sectional view showing the electric power conversion unit according to the first embodiment of the present disclosure.

FIG. 25 is a bottom view showing a semiconductor device according to a second embodiment of the present disclosure.

FIG. 26 is a bottom view showing the semiconductor device according to the second embodiment of the present disclosure.

FIG. 27 is a partially enlarged cross-sectional view along line XXVI-XXVI in FIG. 25.

FIG. 28 is a side view showing a semiconductor device according to a third embodiment of the present disclosure.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a part of an object B”. Further, the phrase “a plane A faces (a first side or a second side) in a direction B” is not limited to the case where the angle of the plane A with respect to the direction B is 90°, but also includes the case where the plane A is inclined to the direction B.

### First Embodiment

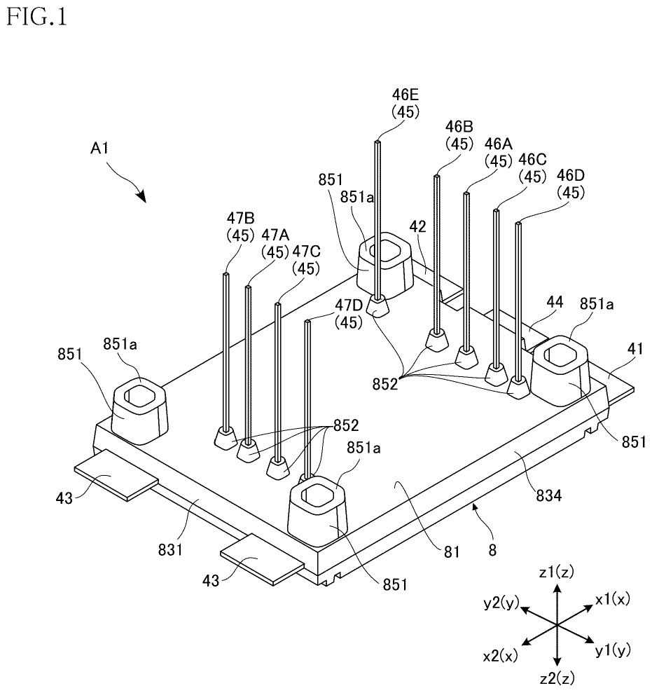

FIGS. 1 to 24 show a semiconductor device and an electric power conversion unit according to a first embodiment of the present disclosure. A semiconductor device A1 of the present embodiment includes a plurality of first semiconductor elements 10A, a plurality of second semiconductor elements 10B, a first heat dissipation member 2A, a first substrate 3A, a first terminal 41, a second terminal 42, a plurality of third terminals 43, a fourth terminal 44, a plurality of control terminals 45, a control terminal support 48, a first conductive member 5, a second conductive member 6, and a sealing resin 8.

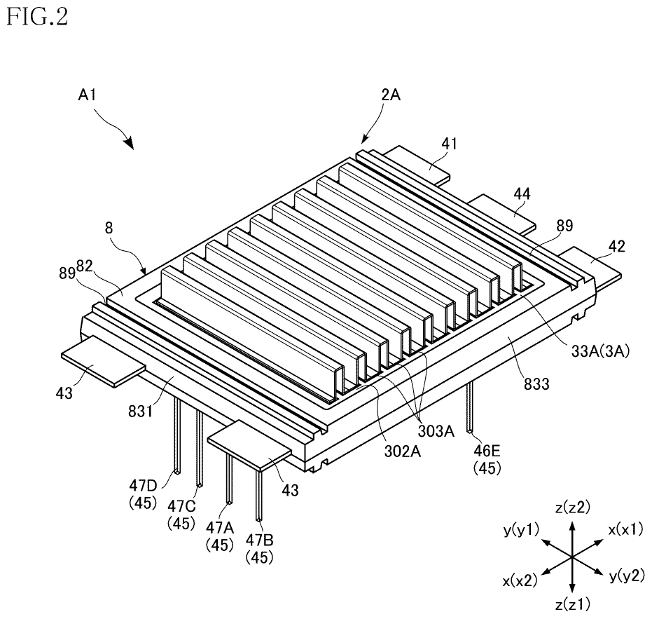

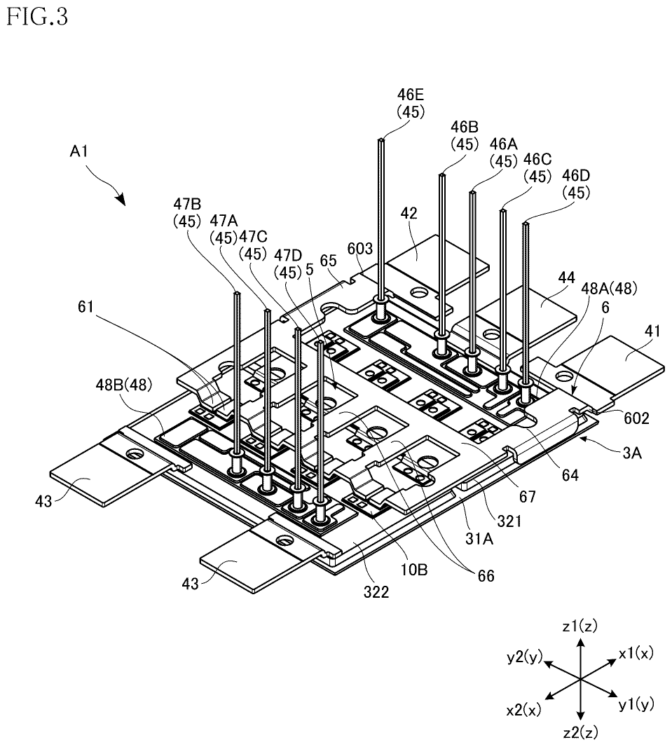

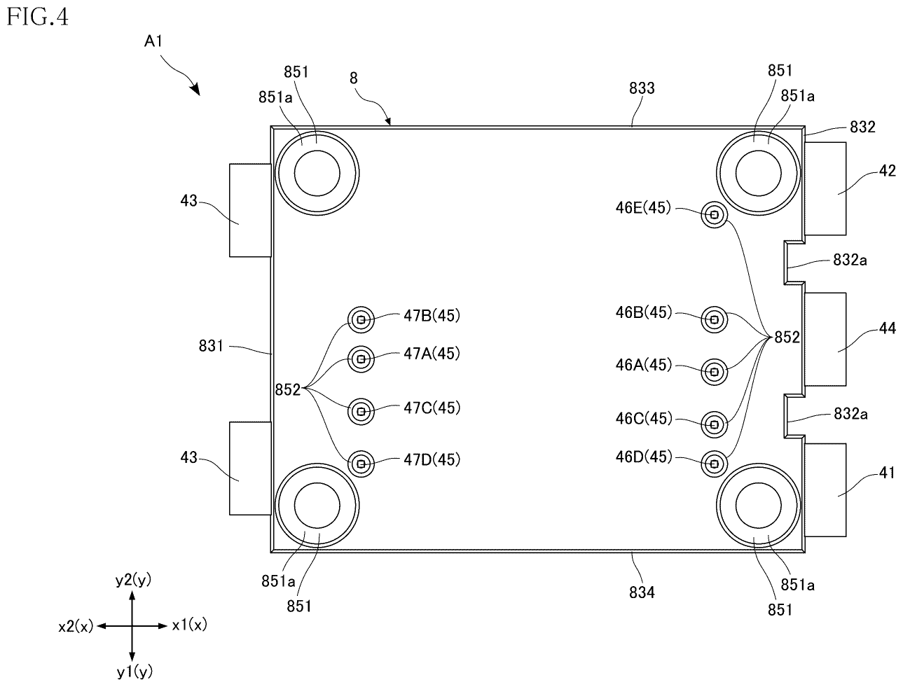

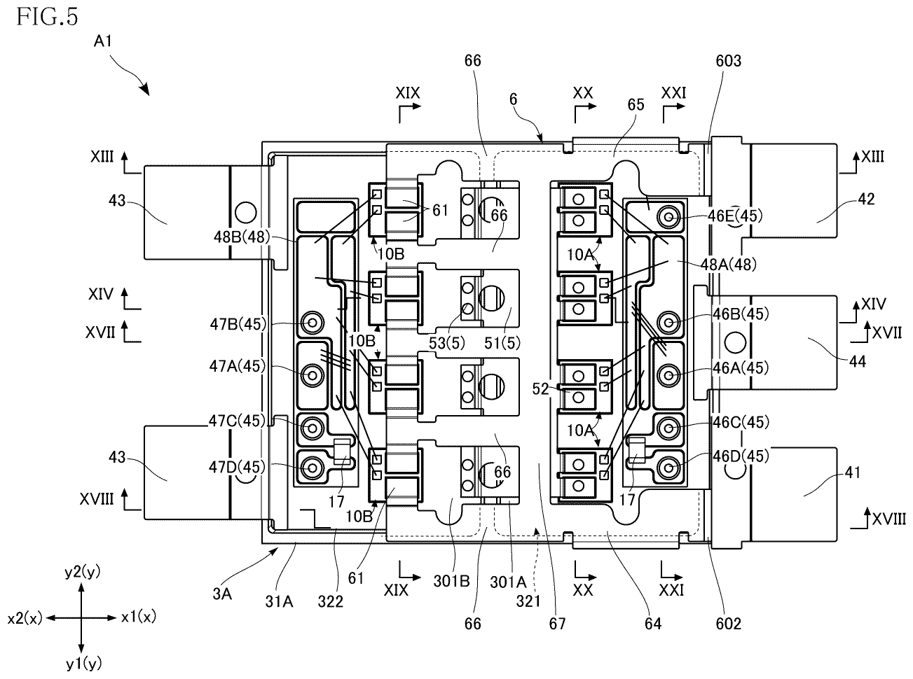

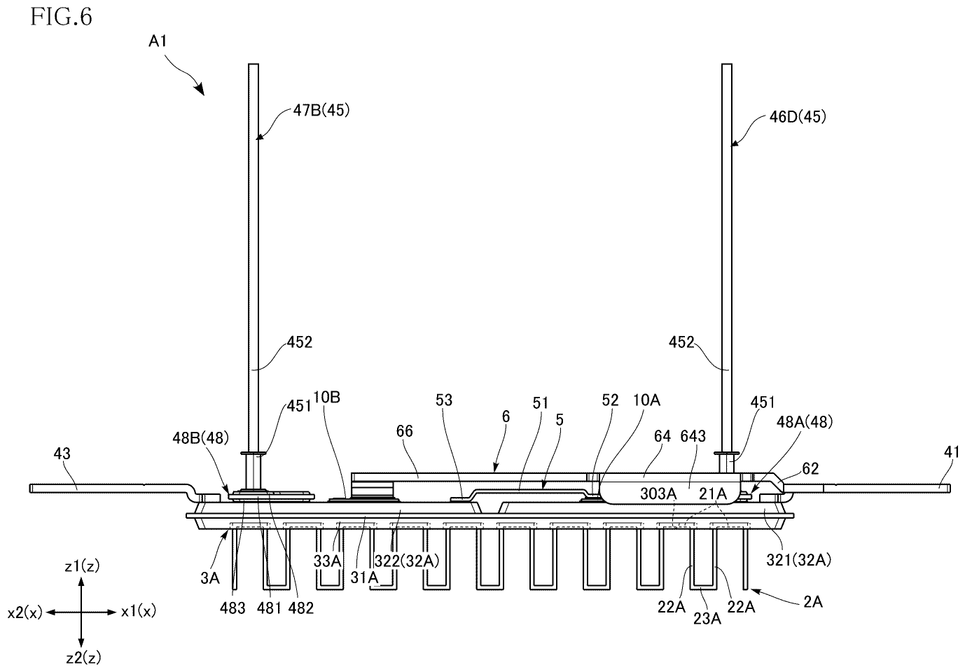

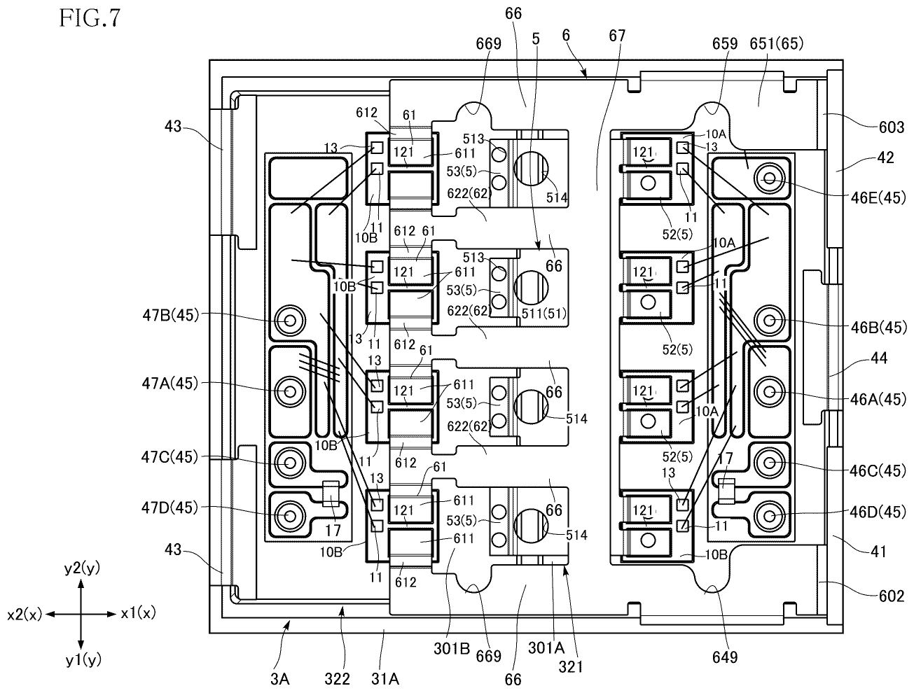

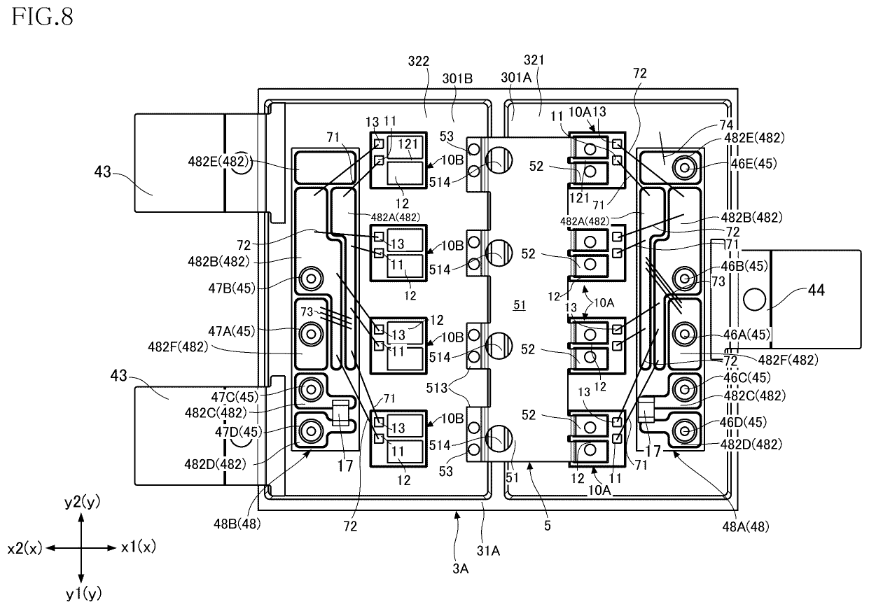

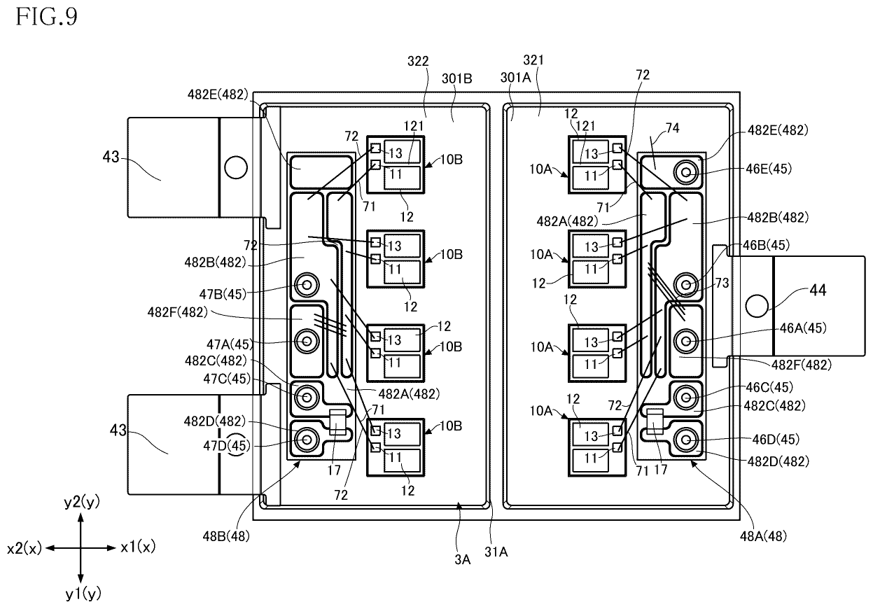

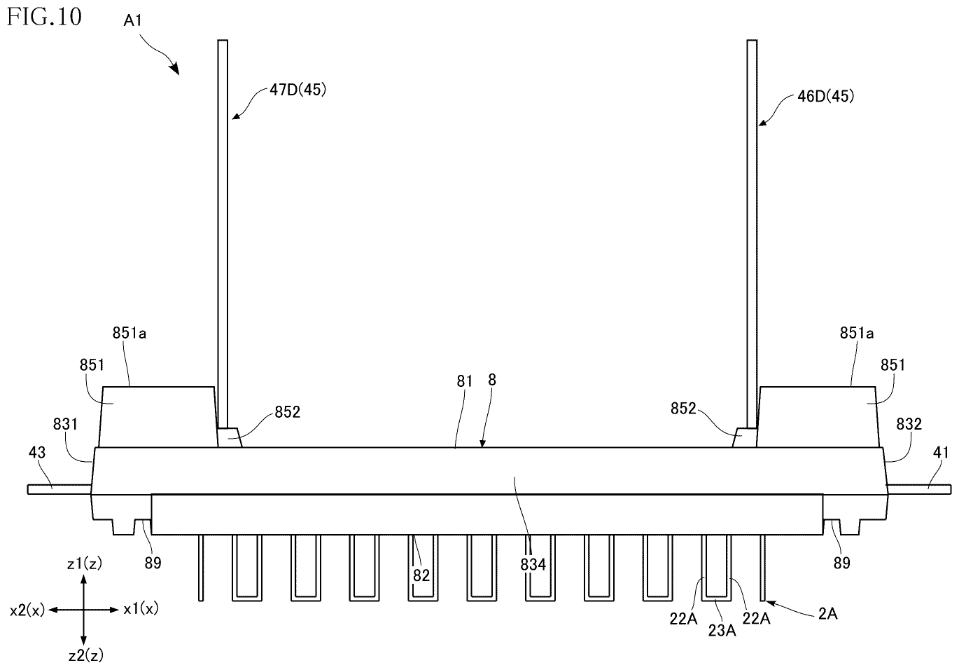

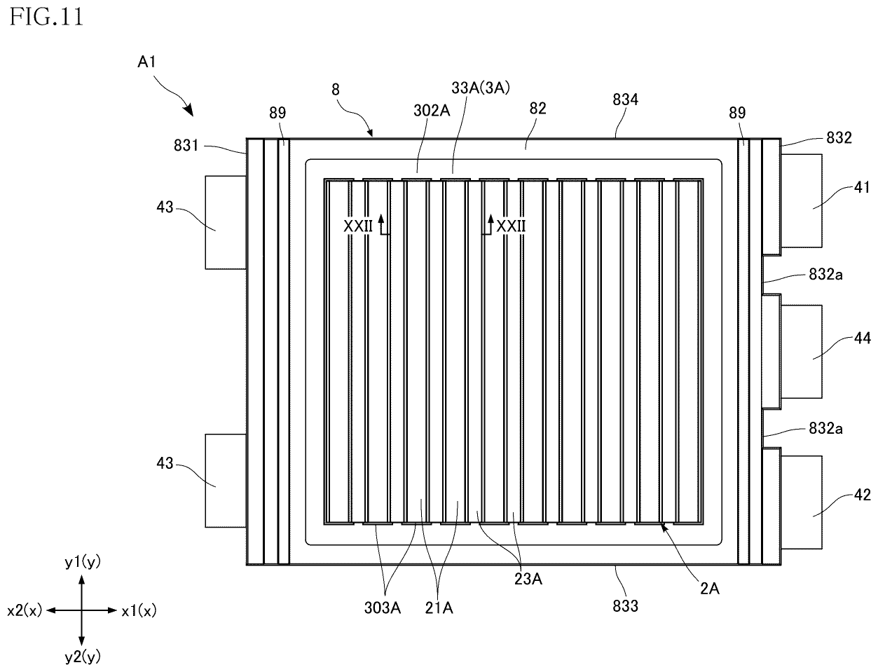

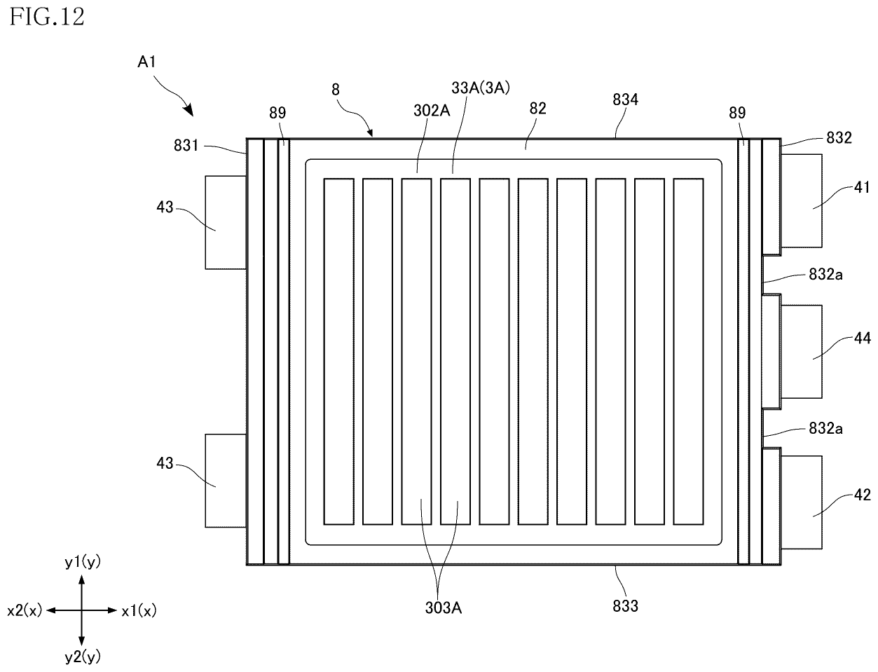

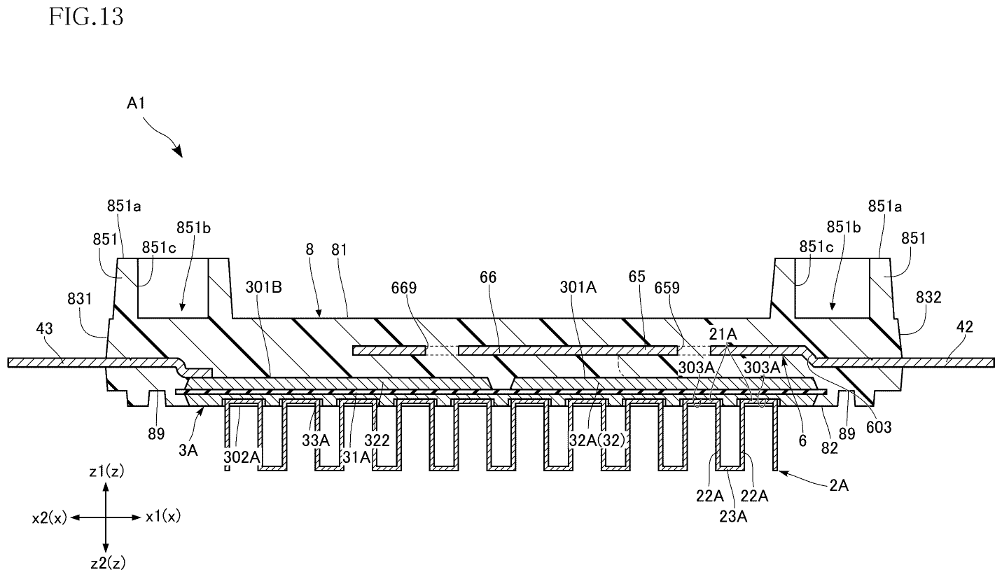

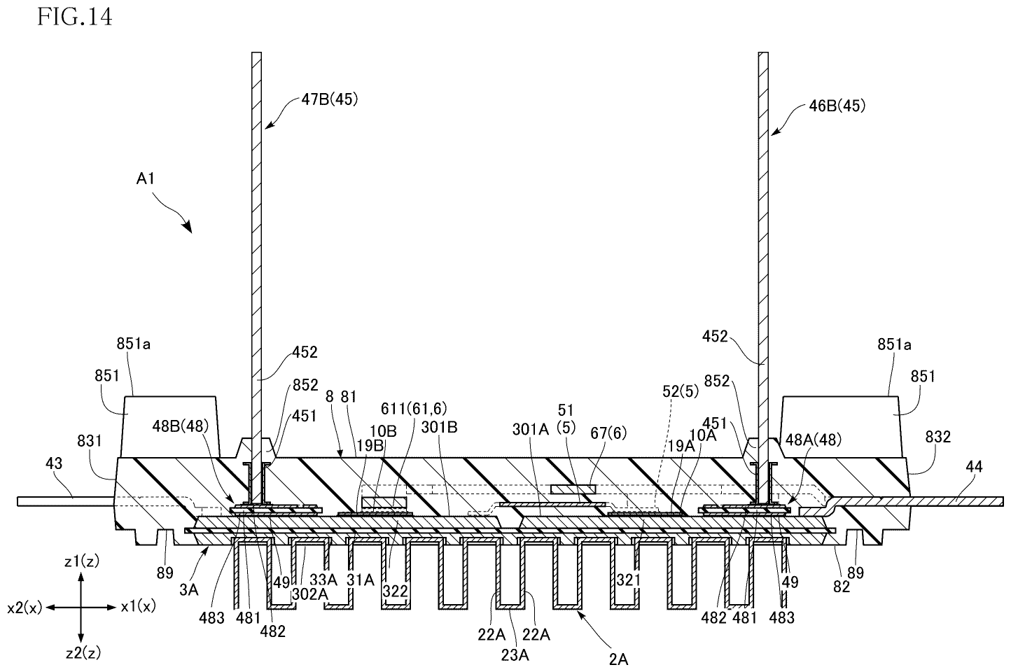

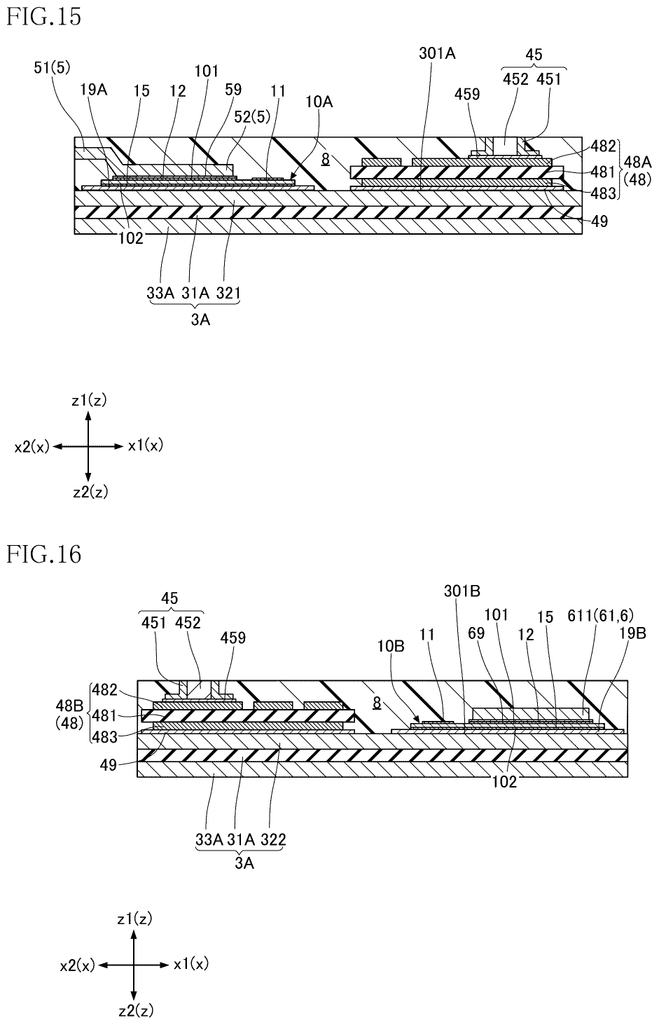

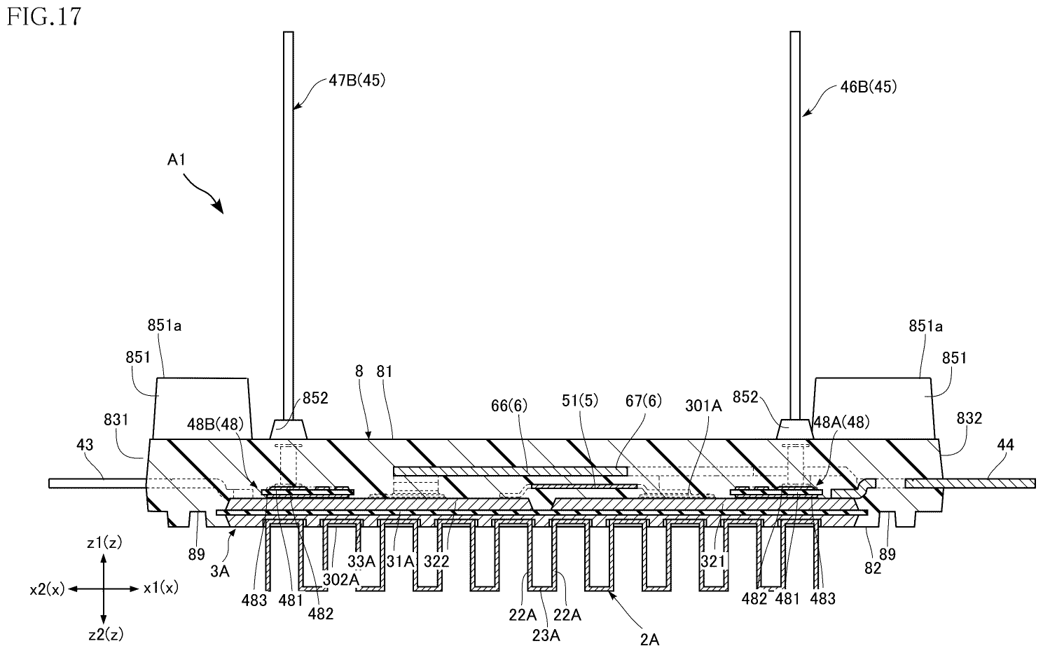

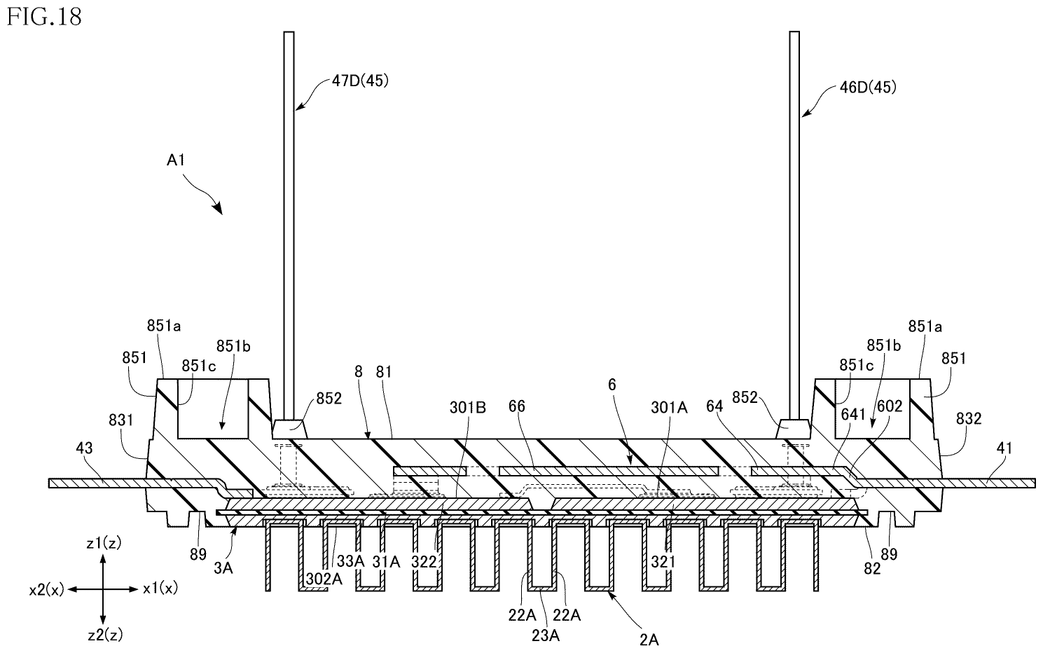

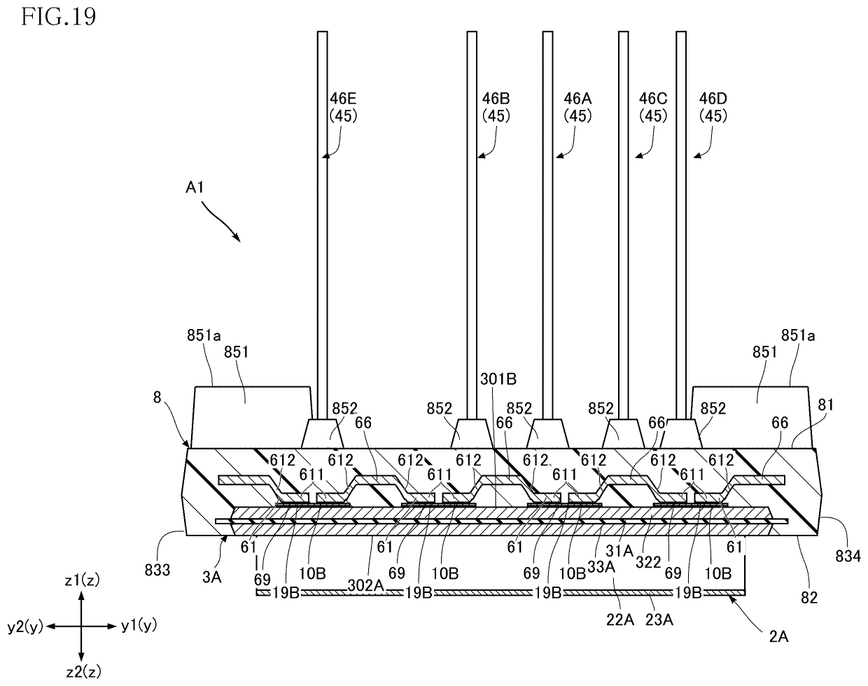

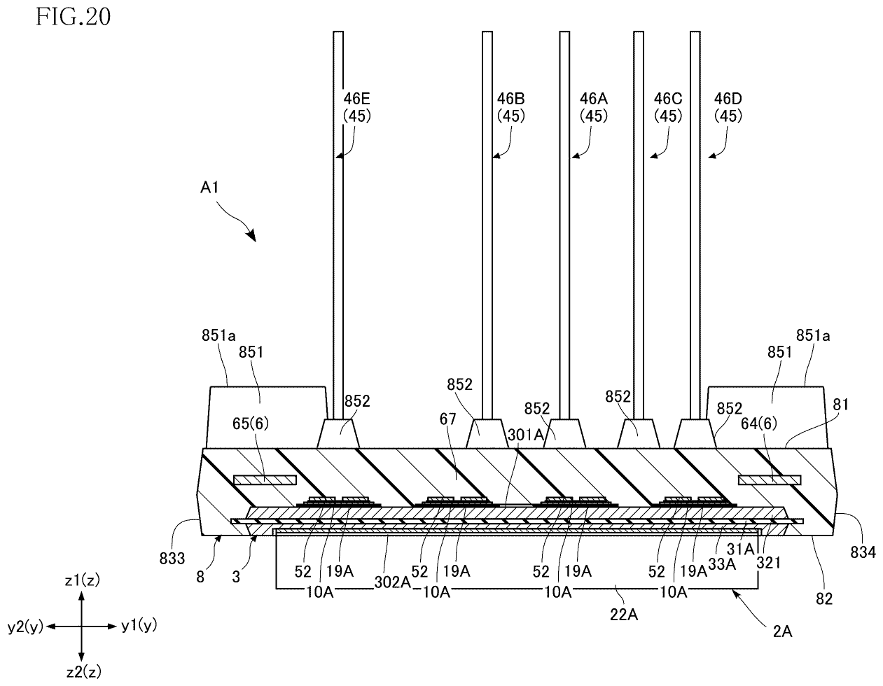

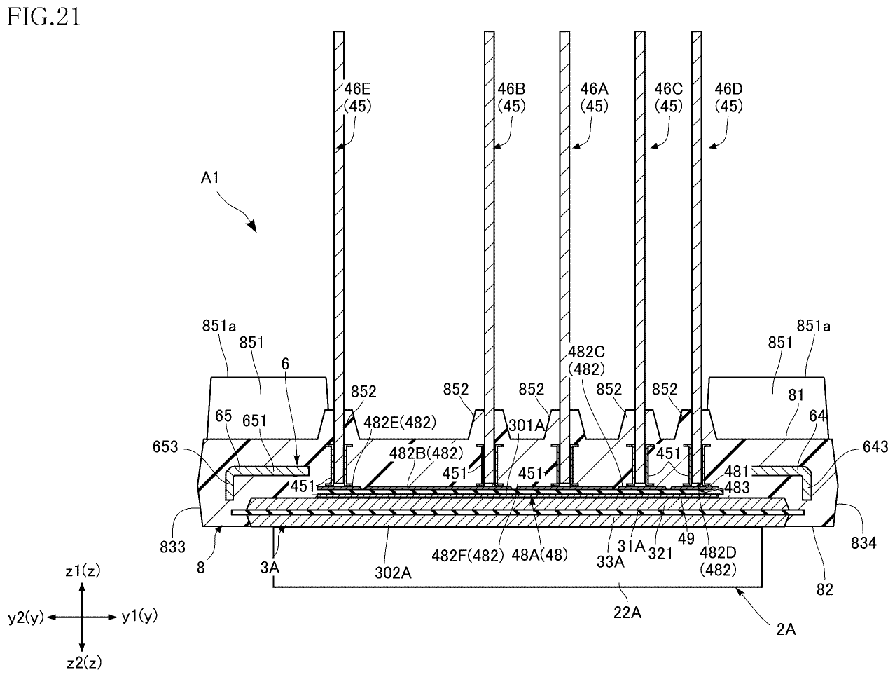

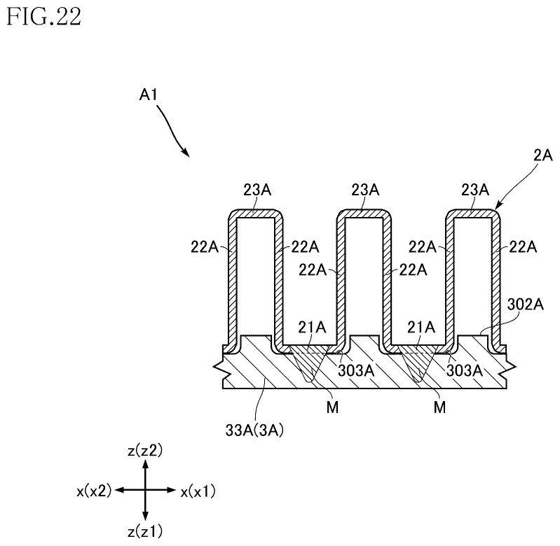

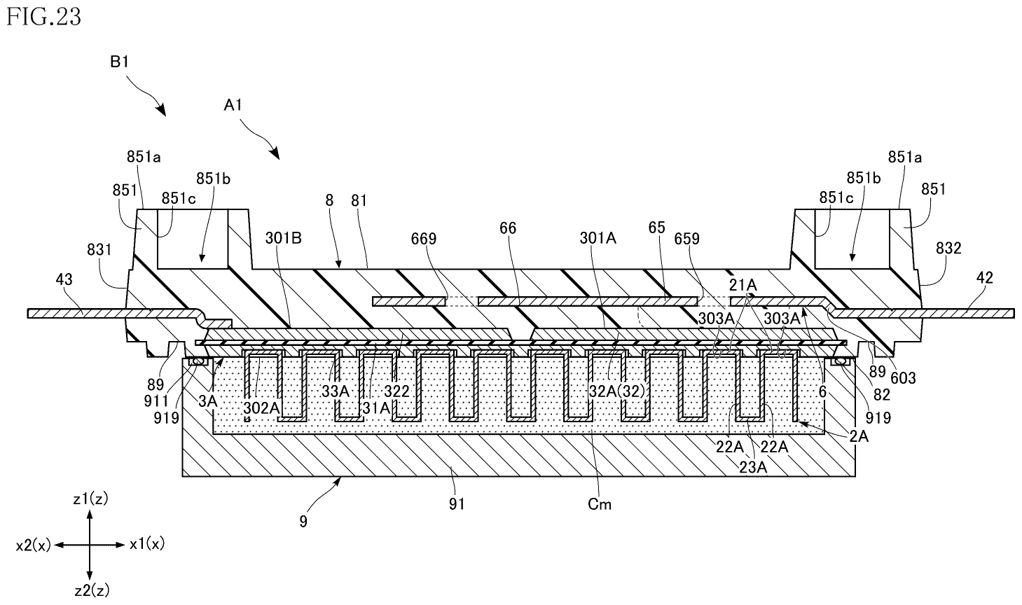

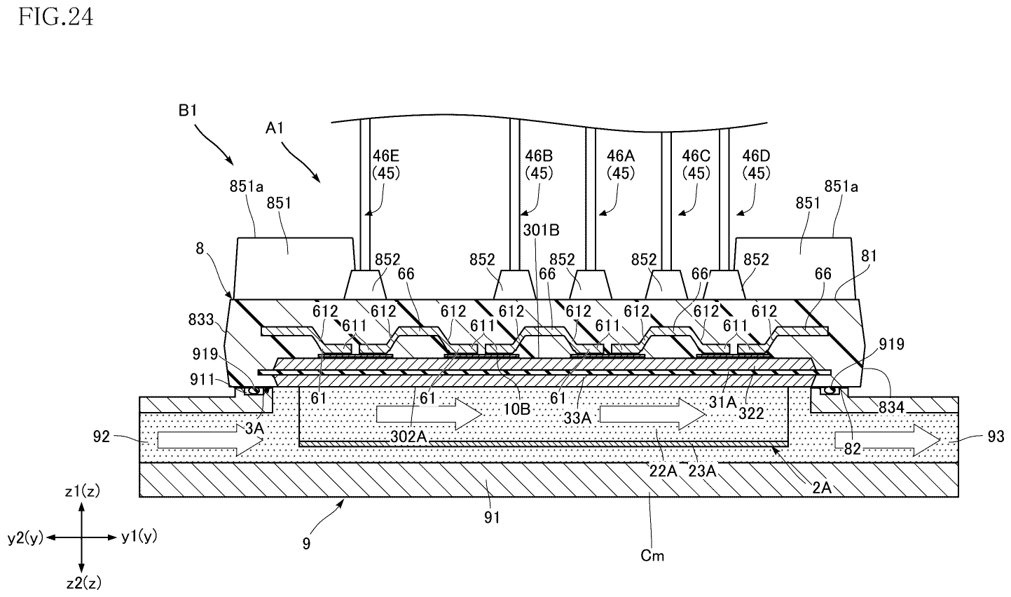

FIG. 1 is a perspective view showing the semiconductor device A1. FIG. 2 is a partial perspective view showing the semiconductor device A1. FIG. 3 is a partial perspective view showing the semiconductor device A1. FIG. 4 is a plan view showing the semiconductor device A1. FIG. 5 is a partial plan view showing the semiconductor device A1. FIG. 6 is a partial side view showing the semiconductor device A1. FIG. 7 is a partially enlarged plan view showing the semiconductor device A1. FIG. 8 is a partial plan view showing the semiconductor device A1. FIG. 9 is a partial plan view showing the semiconductor device A1. FIG. 10 is a side view showing the semiconductor device A1. FIG. 11 is a bottom view showing the semiconductor device A1. FIG. 12 is a partial bottom view showing the semiconductor device A1. FIG. 13 is a cross-sectional view along line XIII-XIII in FIG. 5. FIG. 14 is a cross-sectional view along line XIV-XIV in FIG. 5. FIG. 15 is a partially enlarged cross-sectional view showing the semiconductor device A1. FIG. 16 is a partially enlarged cross-sectional view showing the semiconductor device A1. FIG. 17 is a cross-sectional view along line XVII-XVII in FIG. 5. FIG. 18 is a cross-sectional view along line XVIII-XVIII in FIG. 5. FIG. 19 is a cross-sectional view along line XIX-XIX in FIG. 5. FIG. 20 is a cross-sectional view along line XX-XX in FIG. 5. FIG. 21 is a cross-sectional view along line XXI-XXI in FIG. 5. FIG. 22 is a partially enlarged cross-sectional view along line XXII-XXII in FIG. 11. FIGS. 23 and 24 are cross-sectional views showing an electric power conversion unit B1.

In these figures, one side in a first direction x is referred to as an x1 side in the first direction x, and the other side in the first direction x is referred to as an x2 side in the first direction x. The same applies to a second direction y and a thickness direction z.

First semiconductor elements 10A and second semiconductor elements 10B:

Each of the first semiconductor elements 10A and the second semiconductor elements 10B is an electronic component that forms the functional core of the semiconductor device A1. The first semiconductor elements 10A and the second semiconductor elements 10B are made of a semiconductor material mainly containing silicon carbide (SiC), for example. The semiconductor material is not limited to SiC, and may be silicon (Si), gallium nitride (GaN), or diamond (C). Each of the first semiconductor elements 10A and the second semiconductor elements 10B is a power semiconductor chip having a switching function such as a metal oxide semiconductor field effect transistor (MOSFET). The first semiconductor elements 10A and the second semiconductor elements 10B are MOSFETs in the present embodiment, but may be other transistors such as insulated gate bipolar transistors (IGBTs) in other examples. The first semiconductor elements 10A and the second semiconductor elements 10B are identical to each other. The first semiconductor elements 10A and the second semiconductor elements 10B are n-channel MOSFETs, but may be p-channel MOSFETs instead.

As shown in FIGS. 15 and 16, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart from each other in the thickness direction z. The element obverse surface 101 faces a z1 side in the thickness direction z, and the element reverse surface 102 faces a z2 side in the thickness direction z.

In the present embodiment, the semiconductor device A1 includes four first semiconductor elements 10A and four second semiconductor elements 10B. However, the number of first semiconductor elements 10A and the number of second semiconductor elements 10B are not limited to the present example, and can be changed appropriately according to the performance required for the semiconductor device A1. In the example shown in FIGS. 8 and 9, four first semiconductor elements 10A and four second semiconductor elements 10B are arranged. Each of the number of first semiconductor elements 10A and the number of second semiconductor elements 10B may be two or three, or may be five or greater. The number of first semiconductor elements 10A may be the same as or different from the number of second semiconductor elements 10B. The respective numbers of first semiconductor elements 10A and second semiconductor elements 10B are determined according to the current capacity handled by the semiconductor device A1.

The semiconductor device A1 is configured as a half-bridge switching circuit, for example. In this case, the first semiconductor elements 10A form an upper arm circuit of the semiconductor device A1, and the second semiconductor elements 10B form a lower arm circuit. In the upper arm circuit, the first semiconductor elements 10A are connected in parallel. In the lower arm circuit, the second semiconductor elements 10B are also connected in parallel. Each first semiconductor element 10A is connected in series to a second semiconductor element 10B to form a bridge layer.

As shown in FIGS. 8, 9, and 20 in particular, the first semiconductor elements 10A are mounted on a below-described first conductive portion 321 of the first substrate 3A. In the example shown in FIGS. 8 and 9, the first semiconductor elements 10A are aligned in the second direction y and spaced apart from each other. Each of the first semiconductor elements 10A is electrically bonded to the first conductive portion 321 via a first conductive bonding member 19A. Each of the first semiconductor elements 10A is bonded to the first conductive portion 321, such that the element reverse surface 102 faces the first conductive portion 321. Unlike the present embodiment, the first semiconductor elements 10A may be mounted on a metal member different from a part of a substrate such as a DBC substrate. In this case, the metal member corresponds to the first conductive portion in the present disclosure. The metal member may be supported by the first conductive portion 321, for example.

As shown in FIGS. 8, 9, and 19 in particular, the second semiconductor elements 10B are mounted on a below-described second conductive portion 322 of the first substrate 3A. In the example shown in FIGS. 8 and 9, the second semiconductor elements 10B are aligned in the second direction y and spaced apart from each other. Each of the second semiconductor elements 10B is electrically bonded to the second conductive portion 322 via a second conductive bonding member 19B. Each of the second semiconductor elements 10B is bonded to the second conductive portion 322, such that the element reverse surface 102 faces the second conductive portion 322. As can be understood from FIG. 9, the first semiconductor elements 10A and the second semiconductor elements 10B overlap with each other as viewed in the first direction x, but this overlap is not necessary. Unlike the present embodiment, the second semiconductor elements 10B may be mounted on a metal member different from a part of a substrate such as a DBC substrate. In this case, the metal member corresponds to the second conductive portion in the present disclosure. The metal member may be supported by the second conductive portion 322, for example.

Each of the first semiconductor elements 10A and the second semiconductor elements 10B includes a first obverse-surface electrode 11, a second obverse-surface electrode 12, a third obverse-surface electrode 13, and a reverse-surface electrode 15. The description given below of the configurations of the first obverse-surface electrode 11, the second obverse-surface electrode 12, the third obverse-surface electrode 13, and the reverse-surface electrode 15 is common to all the first semiconductor elements 10A and the second semiconductor elements 10B. The first obverse-surface electrode 11, the second obverse-surface electrode 12, and the third obverse-surface electrode 13 are disposed on the element obverse surface 101. The first obverse-surface electrode 11, the second obverse-surface electrode 12, and the third obverse-surface electrode 13 are insulated by a non-illustrated insulating film. The reverse-surface electrode 15 is disposed on the element reverse surface 102.

The first obverse-surface electrode 11 is a gate electrode, for example, and receives a drive signal (e.g., gate voltage) inputted to drive the first semiconductor element 10A (the second semiconductor element 10B). The second obverse-surface electrode 12 of the first semiconductor element 10A (the second semiconductor element 10B) is a source electrode, for example, and conducts a source current. The second obverse-surface electrode 12 of the present embodiment includes a gate finger 121. The gate finger 121 is a linear insulator that extends in the first direction x, for example, and divides the second obverse-surface electrode 12 into two regions in the second direction y. The third obverse-surface electrode 13 is a source sense electrode, for example, and conducts the source current. The reverse-surface electrode 15 is a drain electrode, for example, and conducts a drain current. The reverse-surface electrode 15 covers the entirety (or substantially the entirety) of the element reverse surface 102. The reverse-surface electrode 15 is formed by silver (Ag) plating, for example.

Each first semiconductor element 10A (each second semiconductor element 10B) switches between a conducting state and a non-conducting state in response to a drive signal (gate voltage) inputted to the first obverse-surface electrode 11 (the gate electrode). In the conducting state, a current flows from the reverse-surface electrode 15 (the drain electrode) to the second obverse-surface electrode 12 (the source electrode). In the non-conducting state, the current does not flow. In short, each first semiconductor element 10A (each second semiconductor element 10B) performs a switching operation. With the switching functions of the first semiconductor elements 10A and the second semiconductor elements 10B, the semiconductor device A1 converts the DC voltage inputted between the fourth terminal 44 and each of the first terminal 41 and the second terminal 42 into AC voltage, for example, and outputs the AC voltage from the third terminals 43.

As shown in FIGS. 5, 8, and 9 in particular, the semiconductor device A1 includes thermistors 17. The thermistors 17 are used as temperature detection sensors. Note that the semiconductor device A1 may include a temperature-sensing diode, for example, in addition to the thermistors 17, or may not include any thermistors 17.

### First Substrate 3A:

The first substrate 3A supports the first semiconductor elements 10A and the second semiconductor elements 10B. The specific configuration of the first substrate 3A is not particularly limited. For example, the first substrate 3A may be a direct bonded copper (DBC) substrate or an active metal brazing (AMB) substrate. The first substrate 3A includes a first insulating layer 31A, a first obverse-surface metal layer 32A, and a first reverse-surface metal layer 33A. The first obverse-surface metal layer 32A includes the first conductive portion 321 and the second conductive portion 322. The dimension of the first substrate 3A in the thickness direction z is at least 0.4 mm and at most 3.0 mm, for example.

The first insulating layer 31A is made of a ceramic material with excellent thermal conductivity, for example. Examples of such a ceramic material include silicon nitride (SiN). The material of the first insulating layer 31A is not limited to ceramic, and may be an insulating resin sheet, for example. The first insulating layer 31A is rectangular in plan view, for example. The dimension of the first insulating layer 31A in the thickness direction z is at least 0.05 mm and at most 1.0 mm, for example.

The first conductive portion 321 supports the first semiconductor elements 10A, and the second conductive portion 322 supports the second semiconductor elements 10B. The first conductive portion 321 and the second conductive portion 322 are formed on the upper surface (the surface facing the z1 side in the thickness direction z) of the first insulating layer 31A. The constituent material of each of the first conductive portion 321 and the second conductive portion 322 contains copper (Cu), for example. The constituent material may contain aluminum (Al) instead of copper (Cu), for example. The first conductive portion 321 and the second conductive portion 322 are spaced apart from each other in the first direction x. The first conductive portion 321 is located on the x1 side in the first direction x from the second conductive portion 322. Each of the first conductive portion 321 and the second conductive portion 322 is rectangular in plan view, for example. The first conductive portion 321 and the second conductive portion 322, together with the first conductive member 5 and the second conductive member 6, form the paths of a main circuit current that is switched by the first semiconductor elements 10A and the second semiconductor elements 10B.

The first conductive portion 321 has a first obverse surface 301A. The first obverse surface 301A is a flat surface facing the z1 side in the thickness direction z. Each of the first semiconductor elements 10A is bonded to the first obverse surface 301A of the first conductive portion 321 via a first conductive bonding member 19A. The second conductive portion 322 has a second obverse surface 301B. The second obverse surface 301B is a flat surface facing the z1 side in the thickness direction z. Each of the second semiconductor elements 10B is bonded to the second obverse surface 301B of the second conductive portion 322 via a second conductive bonding member 19B. The constituent material of each of the first conductive bonding members 19A and the second conductive bonding members 19B is not particularly limited, and may be solder, metal paste containing a metal such as silver (Ag), or a sintered metal containing a metal such as silver (Ag). The dimension of each of the first conductive portion 321 and the second conductive portion 322 in the thickness direction z may be at least 0.1 mm and at most 1.5 mm, for example.

The first reverse-surface metal layer 33A is formed on the lower surface (the surface facing the z2 side in the thickness direction z) of the first insulating layer 31A. The constituent material of the first reverse-surface metal layer 33A is the same as that of the first obverse-surface metal layer 32A. The first reverse-surface metal layer 33A has a first reverse surface 302A and a plurality of first recesses 303A. The first reverse surface 302A is a flat surface facing the z2 side in the thickness direction z. The first reverse surface 302A is exposed from the sealing resin 8. The first reverse-surface metal layer 33A overlaps with the first conductive portion 321 and the second conductive portion 322 in plan view.

As shown in FIGS. 12, 13, and 22, the first recesses 303A are recessed from the first reverse surface 302A to the z1 side in the thickness direction z. In the present embodiment, the first recesses 303A are aligned in the first direction x. The first recesses 303A according to the present embodiment are grooves extending in the second direction y.

### First Heat Dissipation Member 2a:

As shown in FIGS. 2, 6, 10 to 14, and 17 to 22, the first heat dissipation member 2A is disposed on the surface of the first substrate 3A (the first reverse-surface metal layer 33A) on the z2 side in the thickness direction z. The first heat dissipation member 2A has a plurality of first bases 21A, a plurality of first upright portions 22A, and a plurality of first connecting portions 23A. The material of the first heat dissipation member 2A is not particularly limited. For example, the first heat dissipation member 2A is made of a metal plate material. The metal plate material may contain a metal such as copper (Cu), aluminum (Al), or stainless steel, or an alloy of these metals.

The first bases 21A are located on the z1 side in the thickness direction z. The first bases 21A are housed in the respective first recesses 303A. In the first recesses 303A, the first bases 21A are bonded to the first reverse-surface metal layer 33A. The method for bonding the first bases 21A to the first reverse-surface metal layer 33A is not particularly limited, and can be selected as appropriate from a welding method such as laser welding, a method using joints such as brazing, or other methods such as ultrasonic bonding or solid-phase diffusion bonding. In the example shown in FIG. 22, the first bases 21A are bonded to the first reverse-surface metal layer 33A by laser bonding. In this case, parts of the first bases 21A and parts of the first reverse-surface metal layer 33A are melted and solidified to form weld portions M. In the present embodiment, the thickness of each first base 21A in the thickness direction z is smaller than the depth of each first recess 303A in the thickness direction z. The shape of each first base 21A is not particularly limited. In the present embodiment, each of the first bases 21A has a strip shape extending in the second direction y. Each of the first bases 21A may be sized and shaped to fit in a first recess 303A, or may be slightly smaller than a first recess 303A.

The first upright portions 22A are connected to the respective ends of the first bases 21A in the first direction x, and stand in the thickness direction z. The first upright portions 22A protrude beyond the first reverse surface 302A to the z2 side in the thickness direction z. In the present embodiment, the length of each first upright portion 22A in the second direction y is equal (or substantially equal) to the length of each first base 21A in the second direction y. Each of the first upright portions 22A has a strip shape extending in the second direction y, for example.

Each of the first connecting portions 23A connects the z2-side ends in the thickness direction z of first upright portions 22A adjacent to each other in the first direction x. In the present embodiment, the length of each first connecting portion 23A in the second direction y is equal (or substantially equal) to the length of each first upright portion 22A in the second direction y. The shape of each first connecting portion 23A as viewed in the thickness direction z is not particularly limited, and may be a strip shape in the present embodiment. The shape of each first connecting portion 23A as viewed in the second direction y is not particularly limited, and may be a flat shape along the first direction x as illustrated, or may be a dome shape or a ridge shape that bulges to the z2 side in the thickness direction z.

### First Terminal 41, Second Terminal 42, Third Terminals 43, and Fourth Terminal 44:

The first terminal 41, the second terminal 42, the third terminals 43, and the fourth terminal 44 are made of metal plates. The metal plates may contain copper (Cu) or a copper (Cu) alloy. In the example shown in FIGS. 1 to 5, 8, 9, and 11, the semiconductor device A1 includes one first terminal 41, one second terminal 42, one fourth terminal 44, and two third terminals 43, but the respective numbers of these terminals are not particularly limited.

The first terminal 41, the second terminal 42, and the fourth terminal 44 are input terminals for DC voltage that is to be converted. The fourth terminal 44 is a positive electrode (P terminal), and the first terminal 41 and the second terminal 42 are negative electrodes (N terminals). The third terminals 43 are output terminals for the AC voltage resulting from the power conversion by the first semiconductor elements 10A and the second semiconductor elements 10B. Each of the first terminal 41, the second terminal 42, the third terminals 43, and the fourth terminal 44 includes a portion covered with the sealing resin 8 and a portion exposed from the sealing resin 8.

As shown in FIG. 14, the fourth terminal 44 is electrically bonded to the first conductive portion 321. The method for electrical bonding is not particularly limited, and may be ultrasonic bonding, laser bonding, welding, or bonding with solder, metal paste or a sintered silver, as appropriate. As shown in FIGS. 8 and 9 in particular, the fourth terminal 44 is located on the x1 side in the first direction x from the first semiconductor elements 10A and the first conductive portion 321. The fourth terminal 44 is electrically connected to the first conductive portion 321, and also to the reverse-surface electrodes 15 (the drain electrodes) of the first semiconductor elements 10A via the first conductive portion 321.

The first terminal 41 and the second terminal 42 are electrically connected to the second conductive member 6. In the present embodiment, the first terminal 41 and the second conductive member 6 are integrally formed. The first terminal 41 and the second conductive member 6 that are integrally formed have no bonding material or joint, and they may be formed by cutting and bending a single metal plate, for example. In the present embodiment, the second terminal 42 and the second conductive member 6 are also integrally formed. As long as the first terminal 41 and the second terminal 42 are electrically connected to the second conductive member 6, they may be separate components unlike the present embodiment, and may include bonding portions bonded to the second conductive member 6. As shown in FIGS. 5 and 8 in particular, the first terminal 41 and the second terminal 42 are located on the x1 side in the first direction x from the first semiconductor elements 10A and the first conductive portion 321. The first terminal 41 and the second terminal 42 are electrically connected to the second conductive member 6, and also to the second obverse-surface electrodes 12 (the source electrodes) of the respective second semiconductor elements 10B via the second conductive member 6.

As shown in FIGS. 1 to 5, and 11, the first terminal 41, the second terminal 42, and the fourth terminal 44 of the semiconductor device A1 protrude from the sealing resin 8 to the x1 side in the first direction x. The first terminal 41, the second terminal 42, and the fourth terminal 44 are spaced apart from each other. The first terminal 41 and the second terminal 42 are located opposite to each other across the fourth terminal 44 in the second direction y. The first terminal 41 is located on the y1 side in the second direction y from the fourth terminal 44, and the second terminal 42 is located on the y2 side in the second direction y from the fourth terminal 44. The first terminal 41, the second terminal 42, and the fourth terminal 44 overlap with each other as viewed in the second direction y.

As can be seen from FIGS. 8, 9, and 13, the two third terminals 43 are electrically bonded to the second conductive portion 322. The method for electrical bonding is not particularly limited, and may be ultrasonic bonding, laser bonding, welding, or bonding with solder, metal paste or a sintered silver, as appropriate. As shown in FIG. 8 in particular, the two third terminals 43 are located on the x2 side in the first direction x from the second semiconductor elements 10B and the second conductive portion 322. The third terminals 43 are electrically connected to the second conductive portion 322, and also to the reverse-surface electrodes 15 (the drain electrodes) of the second semiconductor elements 10B via the second conductive portion 322. Note that the number of third terminals 43 is not limited to two, and may be one or greater than two. If one third terminal 43 is provided, it is preferable that the third terminal 43 be connected to the central portion of the second conductive portion 322 in the second direction y.

The control terminals 45 are pin-like terminals for controlling the first semiconductor elements 10A and the second semiconductor elements 10B. The control terminals 45 include a plurality of first control terminals 46A to 46E and a plurality of second control terminals 47A to 47D. The first control terminals 46A to 46E are used to control the first semiconductor elements 10A, for example. The second control terminals 47A to 47D are used to control the second semiconductor elements 10B, for example.

### First Control Terminals 46a to 46e:

The first control terminals 46A to 46E are spaced apart from each other in the second direction y. As shown in FIGS. 8, 14, and 21 in particular, the first control terminals 46A to 46E are supported by the first conductive portion 321 via the control terminal support 48 (a first support portion 48A described below). As shown in FIGS. 5 and 8, the first control terminals 46A to 46E are located between the first semiconductor elements 10A and the first, second, and fourth terminals 41, 42, and 44 in the first direction x.

The first control terminal 46A is a terminal (a gate terminal) for receiving input of a drive signal for the first semiconductor elements 10A. The first control terminal 46A receives a drive signal (e.g., gate voltage) for driving the first semiconductor elements 10A.

The first control terminal 46B is a terminal (a source sense terminal) for detecting the source signal of the first semiconductor elements 10A. The voltage (the voltage corresponding to the source current) applied to the second obverse-surface electrodes 12 (the source electrodes) of the first semiconductor elements 10A is detected at the first control terminal 46B.

The first control terminals 46C and 46D are electrically connected to a thermistor 17.

The first control terminal 46E is a terminal (a drain sense terminal) for detecting the drain signal of the first semiconductor elements 10A. The voltage (the voltage corresponding to the drain current) applied to the reverse-surface electrodes 15 (the drain electrodes) of the first semiconductor elements 10A is detected at the first control terminal 46E.

The second control terminals 47A to 47D are spaced apart from each other in the second direction y. As shown in FIGS. 8 and 14 in particular, the second control terminals 47A to 47D are supported by the second conductive portion 322 via the control terminal support 48 (a second support portion 48B described below). As shown in FIGS. 5 and 8, the second control terminals 47A to 47D are located between the second semiconductor elements 10B and the two third terminals 43 in the first direction x.

The second control terminal 47A is a terminal (a gate terminal) for receiving input of a drive signal for the second semiconductor elements 10B. The second control terminal 47A receives a drive signal (e.g., gate voltage) for driving the second semiconductor elements 10B. The second control terminal 47B is a terminal (a source sense terminal) for detecting the source signal of the second semiconductor elements 10B. The voltage (the voltage corresponding to the source current) applied to the second obverse-surface electrodes 12 (the source electrodes) of the second semiconductor elements 10B is detected at the second control terminal 47B. The second control terminals 47C and 47D are electrically connected to a thermistor 17.

Each of the control terminals 45 (the first control terminals 46A to 46E and the second control terminals 47A to 47D) includes a holder 451 and a metal pin 452.

The holder 451 is made of a conductive material. As shown in FIGS. 15 and 16, the holder 451 is bonded to the control terminal support 48 (a first metal layer 482 described below) via a conductive bonding member 459. The holder 451 includes a tubular portion, an upper flange, and a lower flange. The upper flange is connected to the upper end of the tubular portion, and the lower flange is connected to the lower end of the tubular portion. The metal pin 452 is inserted through at least the upper flange and the tubular portion of the holder 451. The holder 451 is covered with the sealing resin 8 (a second protrusion 852 described below).

The metal pin 452 is a rod-like member extending in the thickness direction z. The metal pin 452 is pressed into the holder 451 and supported by the holder 451. The metal pin 452 is electrically connected to the control terminal support 48 (the first metal layer 482 described below) at least through the holder 451. When the lower end (the end on the z2 side in the thickness direction z) of the metal pin 452 is in contact with the conductive bonding member 459 within the insertion hole of the holder 451 as in the example shown in FIGS. 15 and 16, the electrical connection of the metal pin 452 to the control terminal support 48 is established through the conductive bonding member 459.

### Control Terminal Support 48:

The control terminal support 48 supports the control terminals 45. In the thickness direction z, the control terminal support 48 is located between the first and second obverse surfaces 301A and 301B and the plurality of control terminals 45.

The control terminal support 48 includes a first support portion 48A and a second support portion 48B. The first support portion 48A is disposed on the first conductive portion 321 and supports the first control terminals 46A to 46E out of the plurality of control terminals 45. As shown in FIG. 15, the first support portion 48A is bonded to the first conductive portion 321 via a bonding member 49. The bonding member 49 can be either conductive or insulating, and solder is used in one example. The second support portion 48B is disposed on the second conductive portion 322 and supports the second control terminals 47A to 47D out of the plurality of control terminals 45. As shown in FIG. 16, the second support portion 48B is bonded to the second conductive portion 322 via a bonding member 49.

The control terminal support 48 (each of the first support portion 48A and the second support portion 48B) may be composed of a direct bonded copper (DBC) substrate, for example. The control terminal support 48 includes a stack of an insulating layer 481, a first metal layer 482, and a second metal layer 483.

The insulating layer 481 is made of a ceramic material, for example. The insulating layer 481 is rectangular in plan view, for example.

As shown in FIGS. 15 and 16 in particular, the first metal layer 482 is formed on the upper surface of the insulating layer 481. Each of the control terminals 45 stands on the first metal layer 482. The first metal layer 482 contains copper (Cu) or a copper (Cu) alloy, for example. As shown in FIG. 8 in particular, the first metal layer 482 includes a first region 482A, a second region 482B, a third region 482C, a fourth region 482D, a fifth region 482E, and a sixth region 482F. The first region 482A, the second region 482B, the third region 482C, the fourth region 482D, the fifth region 482E, and the sixth region 482F are spaced apart and insulated from each other.

A plurality of wires 71 are bonded to the first region 482A. The wires 71 electrically connect the first region 482A to the first obverse-surface electrodes 11 (the gate electrodes) of the first semiconductor elements 10A (the second semiconductor elements 10B). A plurality of wires 73 are connected to the first region 482A and the sixth region 482F. Thus, the sixth region 482F is electrically connected to the first obverse-surface electrodes 11 (the gate electrodes) of the first semiconductor elements 10A (the second semiconductor elements 10B) via the wires 73 and 71. As shown in FIG. 8, the first control terminal 46A is bonded to the sixth region 482F of the first support portion 48A, and the second control terminal 47A is bonded to the sixth region 482F of the second support portion 48B.

A plurality of wires 72 are bonded to the second region 482B. The wires 72 electrically connect the second region 482B to the third obverse-surface electrodes 13 (the source sense electrodes) of the first semiconductor elements 10A (the second semiconductor elements 10). As shown in FIG. 8, the first control terminal 46B is bonded to the second region 482B of the first support portion 48A, and the second control terminal 47B is bonded to the second region 482B of the second support portion 48B.

A thermistor 17 is bonded to the third region 482C and the fourth region 482D. As shown in FIG. 8, the first control terminals 46C and 46D are respectively bonded to the third region 482C and the fourth region 482D of the first support portion 48A. In addition, the second control terminals 47C and 47D are respectively bonded to the third region 482C and the fourth region 482D of the second support portion 48B.

A wire 74 is bonded to the fifth region 482E of the first support portion 48A. The wire 74 electrically connects the fifth region 482E to the first conductive portion 321. As shown in FIG. 8, the first control terminal 46E is bonded to the fifth region 482E of the first support portion 48A. The fifth region 482E of the second support portion 48B is not electrically connected to any element. The wires 71 to 74 may be bonding wires, for example. The constituent material of the wires 71 to 74 may contain gold (Au), aluminum (Al), or copper (Cu), for example.

As shown in FIGS. 15 and 16 in particular, the second metal layer 483 is formed on the lower surface of the insulating layer 481. As shown in FIG. 15, the second metal layer 483 of the first support portion 48A is bonded to the first conductive portion 321 via the bonding member 49. As shown in FIG. 16, the second metal layer 483 of the second support portion 48B is bonded to the second conductive portion 322 via the bonding member 49.

### First Conductive Member 5 and Second Conductive Member 6:

The first conductive member 5 and the second conductive member 6, together with the first conductive portion 321 and the second conductive portion 322, form the paths of the main circuit current that is switched by the first semiconductor elements 10A and the second semiconductor elements 10B. The first conductive member 5 and the second conductive member 6 are spaced apart from the first obverse surface 301A and the second obverse surface 301B to the z1 side in the thickness direction z. In plan view, the first conductive member 5 and the second conductive member 6 overlap with the first obverse surface 301A and the second obverse surface 301B. In the present embodiment, each of the first conductive member 5 and the second conductive member 6 is made of a metal plate. The metal may contain copper (Cu) or a copper (Cu) alloy, for example. Specifically, the first conductive member 5 and the second conductive member 6 are metal plates having been bent as needed.

The first conductive member 5 is connected to the second obverse-surface electrodes 12 (the source electrodes) of the first semiconductor elements 10A and the second conductive portion 322, and electrically connects the second obverse-surface electrodes 12 of the first semiconductor elements 10A and the second conductive portion 322. The first conductive member 5 forms a path of the main circuit current that is switched by the first semiconductor elements 10A. As shown in FIGS. 7 and 8, the first conductive member 5 includes a main portion 51, a plurality of first bonding portions 52, and a plurality of second bonding portions 53.

The main portion 51 is located between the first semiconductor elements 10A and the second conductive portion 322 in the first direction x, and has the shape of a strip extending in the second direction y in plan view. The main portion 51 overlaps with both the first conductive portion 321 and the second conductive portion 322 in plan view, and is spaced apart from the first obverse surface 301A and the second obverse surface 301B to the z1 side in the thickness direction z. As shown in FIG. 17 in particular, the main portion 51 is located on the z2 side in the thickness direction z from a plurality of third path portions 66 and a fourth path portion 67 of the second conductive member 6 described below, and is closer to the first obverse surface 301A and the second obverse surface 301B than the third path portions 66 and the fourth path portion 67.

In the present embodiment, the main portion 51 is parallel to the first obverse surface 301A and the second obverse surface 301B.

As shown in FIG. 8 in particular, the main portion 51 extends continuously in the second direction y to correspond to a region in which the first semiconductor elements 10A are positioned. In the present embodiment, the main portion 51 has a plurality of first openings 514 as shown in FIGS. 7, 8, and 14 in particular. The first openings 514 may be through-holes extending in the thickness direction z (the direction of the plate thickness of the main portion 51), for example. The first openings 514 are spaced apart from each other in the second direction y. The first openings 514 are provided for the respective first semiconductor elements 10A. In the present embodiment, the main portion 51 has four first openings 514, each of which corresponds in position in the second direction y to one of the plurality of (four) first semiconductor elements 10A.

As shown in FIGS. 8 and 14 in particular, the first openings 514 of the present embodiment overlap with the gap between the first conductive portion 321 and the second conductive portion 322 in plan view. The first openings 514 are provided to facilitate the flow of a molten resin material between the upper side (on the z1 side in the thickness direction z) and the lower side (on the z2 side in the thickness direction z) around the main portion 51 (the first conductive member 5) when the molten resin material is injected in the process of forming the sealing resin 8.

As shown in FIG. 8 in particular, the first bonding portions 52 and the second bonding portions 53 are connected to the main portion 51 and disposed to correspond to the first semiconductor elements 10A. Specifically, the first bonding portions 52 are located on the x1 side in the first direction x from the main portion 51. The second bonding portions 53 are located on the x2 side in the first direction x from the main portion 51. As shown in FIG. 15, each of the first bonding portions 52 is bonded to the second obverse-surface electrode 12 of a corresponding first semiconductor element 10A via a conductive bonding member 59. Each of the second bonding portions 53 is bonded to the second conductive portion 322 via a conductive bonding member 59. The material of the conductive bonding members 59 is not particularly limited, and may be solder, metal paste, or sintered metal. In the present embodiment, each of the first bonding portions 52 includes two regions spaced apart from each other in the second direction y. The two regions are bonded to the second obverse-surface electrode 12 of a corresponding first semiconductor element 10A on the respective sides of the gate finger 121 of the second obverse-surface electrode 12 in the second direction y.

The second conductive member 6 electrically connects the second obverse-surface electrodes 12 (the source electrodes) of the second semiconductor elements 10B to the first terminal 41 and the second terminal 42. The second conductive member 6 is integrally formed with the first terminal 41 and the second terminal 42. The second conductive member 6 forms a path of the main circuit current that is switched by the second semiconductor elements 10B. As shown in FIGS. 3, 5 to 7, 13, 14, 17 to 19, the second conductive member 6 includes a plurality of third bonding portions 61, a first path portion 64, a second path portion 65, a plurality of third path portions 66, and a fourth path portion 67. In the illustrated example, the second conductive member 6 includes a first ramp portion 602 and a second ramp portion 603.

The third bonding portions 61 are bonded to the respective second semiconductor elements 10B. Each of the third bonding portions 61 is bonded to the second obverse-surface electrode 12 of a second semiconductor element 10B via a conductive bonding member 69. The material of the conductive bonding members 69 is not particularly limited, and may be solder, metal paste, or sintered metal. In the present embodiment, each of the third bonding portions 61 includes two flat sections 611 and two first inclined sections 612.

The two flat sections 611 are aligned in the second direction y. The two flat sections 611 are spaced apart from each other in the second direction y. The shape of each flat section 611 is not particularly limited, and is rectangular in the illustrated example. The two flat sections 611 are bonded to the second obverse-surface electrode 12 of a corresponding second semiconductor element 10B on the respective sides of the gate finger 121 of the second obverse-surface electrode 12 in the second direction y.

The two first inclined sections 612 are connected to the outer ends of the respective two flat sections 611 in the second direction y. In other words, the first inclined section 612 on the y1 side in the second direction y is connected to the y1-side end of the flat section 611 located on the y1 side in the second direction y. The first inclined section 612 located on the y2 side in the second direction y is connected to the y2-side end of the flat section 611 located on the y2 side in the second direction y. Each of the first inclined sections 612 is inclined toward the z1 side in the thickness direction z with an increasing distance from the flat section 611 in the second direction y.

The first path portion 64 is located between the third bonding portions 61 and the first terminal 41. In the illustrated example, the first path portion 64 is connected to the first terminal 41 via the first ramp portion 602. The first path portion 64 overlaps with the first conductive portion 321 in plan view. The first path portion 64 generally extends in the first direction x.

The first path portion 64 includes a first band-shaped section 641 and a first extended section 643. The first band-shaped section 641 is located on the x2 side in the first direction x from the first terminal 41, and is parallel to (or substantially parallel to) the first obverse surface 301A. The first band-shaped section 641 generally extends in the first direction x. In the illustrated example, the first band-shaped section 641 has a recess 649. The recess 649 is a portion of the first band-shaped section 641 that is recessed toward the y1 side in the second direction y. In FIG. 5, a first conductive portion 321 is visible through the recess 649.

The first extended section 643 extends from the y1-side end of the first band-shaped section 641 in the second direction y toward the z2 side in the thickness direction z. The first extended section 643 is spaced apart from the first conductive portion 321. In the illustrated example, the first extended section 643 extends in the thickness direction z and has a rectangular shape elongated in the first direction x. Note that the first path portion 64 may be configured without the first extended section 643.

The second path portion 65 is located between the third bonding portions 61 and the second terminal 42. In the illustrated example, the second path portion 65 is connected to the second terminal 42 via the second ramp portion 603. The second path portion 65 overlaps with the first conductive portion 321 in plan view. The second path portion 65 generally extends in the first direction x.

The second path portion 65 includes a second band-shaped section 651 and a second extended section 653. The second band-shaped section 651 is located on the x2 side in the first direction x from the second terminal 42, and is parallel to (or substantially parallel to) the first obverse surface 301A. The second band-shaped section 651 generally extends in the first direction x. In the illustrated example, the second band-shaped section 651 has a recess 659. The recess 659 is a portion of the second band-shaped section 651 that is recessed toward the y2 side in the second direction y. In FIG. 5, a first conductive portion 321 is visible through the recess 659.

The second extended section 653 extends from the y2-side end of the second band-shaped section 651 in the second direction y toward the z2 side in the thickness direction z. The second extended section 653 is spaced apart from the first conductive portion 321. In the illustrated example, the second extended section 653 extends in the thickness direction z and has a rectangular shape that is elongated in the first direction x. Note that the second path portion 65 may be configured without the second extended section 653.

The third path portions 66 are individually connected to the third bonding portions 61. The third path portions 66 extend in the first direction x, and are spaced apart from each other in the second direction y. The number of third path portions 66 is not particularly limited. In the illustrated example, five third path portions 66 are provided. Each of the third path portions 66 is located either between two of the second semiconductor elements 10B in the second direction y or outside the second semiconductor elements 10B in the second direction y.

The two outermost third path portions 66 in the second direction y are formed with recesses 669. Each of the recesses 669 is recessed from the inner side toward the outer side in the second direction y. In the illustrated example, each of the two outermost third path portions 66 has one recess 669. In FIG. 5, the second conductive portion 322 is visible through the recesses 669.

In the present embodiment, each of the third bonding portions 61 is located between two third path portions 66 adjacent in the second direction y. Each of the third bonding portions 61 has two first inclined sections 612, one on the y1 side in the second direction y and the other on the y2 side in the second direction y. The first inclined section 612 on the y1 side is connected to one of the two adjacent third path portions 66 that is located on the y1 side in the second direction y. The first inclined section 612 on the y2 side is connected to one of the two adjacent third path portions 66 that is located on the y2 side in the second direction y.

The fourth path portion 67 is connected to the ends of the respective third path portions 66 on the x1 side in the first direction x. The fourth path portion 67 extends in the second direction y. The fourth path portion 67 is connected to the x2-side end of the first band-shaped section 641 of the first path portion 64 in the first direction x, and to the x2-side end of the second band-shaped section 651 of the second path portion 65 in the first direction x. In the illustrated example, the fourth path portion 67 is connected to the first path portion 64 at the end on the y1 side in the second direction y and to the second path portion 65 at the end on the y2 side in the second direction y.

### Sealing Resin 8:

The sealing resin 8 covers the first semiconductor elements 10A, the second semiconductor elements 10B, the first substrate 3A (except for the first reverse surface 302A), a part of each of the first terminal 41, the second terminal 42, the third terminals 43, and the fourth terminal 44, a part of each of the control terminals 45, the control terminal support 48, the first conductive member 5, the second conductive member 6, and the wires 71 to 74. The sealing resin 8 may be made of a black epoxy resin, for example. The sealing resin 8 may be formed by molding, for example. The sealing resin 8 may have a dimension of about 35 mm to 60 mm in the first direction x, a dimension of about 35 mm to 50 mm in the second direction y, and a dimension of about 4 mm to 15 mm in the thickness direction z. These dimensions are measured at the largest portions in the respective directions. The sealing resin 8 has a resin obverse surface 81, a resin reverse surface 82, and resin side surfaces 831 to 834.

As shown in FIGS. 10, 13, and 19 in particular, the resin obverse surface 81 and the resin reverse surface 82 are spaced apart from each other in the thickness direction z. The resin obverse surface 81 faces the z1 side in the thickness direction z, and the resin reverse surface 82 faces the z2 side in the thickness direction z. The control terminals 45 (the first control terminals 46A to 46E and the second control terminals 47A to 47D) protrude from the resin obverse surface 81. As shown in FIG. 11, the resin reverse surface 82 has the shape of a frame surrounding the first reverse surface 302A (the lower surface of the first reverse-surface metal layer 33A) of the first substrate 3A in plan view. The first reverse surface 302A of the first substrate 3A is exposed from the resin reverse surface 82, and is flush with the resin reverse surface 82, for example. The resin side surfaces 831 to 834 are connected to both the resin obverse surface 81 and the resin reverse surface 82, and are located between the resin obverse surface 81 and the resin reverse surface 82 in the thickness direction z. As shown in FIG. 4 in particular, the resin side surface 831 and the resin side surface 832 are spaced apart from each other in the first direction x. The resin side surface 831 faces the x2 side in the first direction x, and the resin side surface 832 faces the x1 side in the first direction x. The two third terminals 43 protrude from the resin side surface 831, and the first terminal 41, the second terminal 42, and the fourth terminal 44 protrude from the resin side surface 832. As shown in FIG. 4 in particular, the resin side surface 833 and the resin side surface 834 are spaced apart from each other in the second direction y. The resin side surface 833 faces the y2 side in the second direction y, and the resin side surface 834 faces the y1 side in the second direction y.

As shown in FIG. 4, the resin side surface 832 has a plurality of recesses 832a. Each of the recesses 832a is recessed in the first direction x in plan view. The recesses 832a include one formed between the first terminal 41 and the fourth terminal 44, and one formed between the second terminal 42 and the fourth terminal 44 in plan view. The recesses 832a are provided to increase the creepage distance along the resin side surface 832 between the first terminal 41 and the fourth terminal 44, and also to increase the creepage distance along the resin side surface 832 between the second terminal 42 and the fourth terminal 44.

As shown in FIGS. 13 and 14 in particular, the sealing resin 8 includes a plurality of first protrusions 851, a plurality of second protrusions 852, and a resin cavity 86.

The first protrusions 851 protrude from the resin obverse surface 81 in the thickness direction z. The first protrusions 851 are located near the four corners of the sealing resin 8 in plan view. Each of the first protrusions 851 has a first protrusion end surface 851a at its end (the end on the z1 side in the thickness direction z). The first protrusion end surface 851a of each first protrusion 851 is parallel to (or substantially parallel to) the resin obverse surface 81 and located in the same plane (x-y plane). Each of the first protrusions 851 has the shape of a hollow truncated cone with a bottom, for example. The first protrusions 851 serve as spacers when the semiconductor device A1 is mounted on, for example, a control circuit board of a device that operates with the power generated by the semiconductor device A1. Each of the first protrusions 851 has a recess 851b and an inner wall surface 851c of the recess 851b. Each of the first protrusions 851 is columnar, which is preferably a cylindrical column. The recess 851b has a cylindrical shape, preferably with the inner wall surface 851c defining a perfect circle in plan view.

The sealing resin 8 includes a groove 89. The groove 89 is recessed from the resin reverse surface 82 to the z1 side in the thickness direction z. The groove 89 extends across the resin reverse surface 82 in the second direction y. In the illustrated example, the sealing resin 8 has two grooves 89. The two grooves 89 are spaced apart from each other in the first direction x. The first reverse-surface metal layer 33A (the first reverse surface 302A) is located between the two grooves 89.

The semiconductor device A1 may be mechanically fastened to the control circuit board or the like by screwing, for example. In such a case, each first protrusion 851 may be formed with an internal thread on the inner wall surface 851c of the recess 851b. For example, an insert nut may be inserted into the recess 851b of each first protrusion 851.

As shown in FIG. 14 in particular, the second protrusions 852 protrude from the resin obverse surface 81 in the thickness direction z. The second protrusions 852 overlap with the control terminals 45 in plan view. The metal pin 452 of each control terminal 45 protrudes from a second protrusion 852. Each of the second protrusions 852 has the shape of a truncated cone. Each of the second protrusions 852 covers the holder 451 and a portion of the metal pin 452 of a control terminal 45.

As shown in FIGS. 23 and 24, the electric power conversion unit B1 includes the semiconductor device A1 and a cooling device 9.

The cooling device 9 is disposed on the z2 side in the thickness direction z with respect to the semiconductor device A1. The cooling device 9 has a housing 91.

The housing 91 is a box-shaped member made of metal or resin, for example. The housing 91 houses the first heat dissipation member 2A. In the present embodiment, the housing 91 is attached to the semiconductor device A1 via a sealant 919. The sealant 919 is disposed between an end of the housing 91 and the resin reverse surface 82 of the sealing resin 8, and maintains the airtightness of the internal space of the housing 91. In the present embodiment, the housing 91 is formed with a groove 911. The groove 911 has an annular shape as viewed in the thickness direction z, and houses a part of the sealant 919.

The housing 91 is filled with a cooling medium Cm. The cooling medium Cm flows within the housing 91. In the present embodiment, the cooling device 9 has a supply section 92 and a discharge section 93. The supply section 92 and the discharge section 93 are attached to the respective sides of the housing 91 in the second direction y. The supply section 92 supplies the cooling medium Cm to the housing 91. The discharge section 93 discharges the cooling medium Cm that has flowed through the housing 91. In this way, the cooling medium Cm flows in the second direction y in the housing 91. Note that “the cooling medium Cm flows in the second direction y” does not mean that only the flow velocity component in the second direction y exists, but includes the state in which the cooling medium Cm moves in the second direction y as a whole while including the flow velocity components in the first direction x and the thickness direction z.

Next, the advantages of the present embodiment will be described.

The first heat dissipation member 2A has the first bases 21A and the first upright portions 22A. The first upright portions 22A protrude from the first reverse surface 302A in the thickness direction z to increase the heat transfer area. Each of the first bases 21A is housed in a first recess 303A and bonded to the first reverse-surface metal layer 33A within the first recess 303A. This makes it possible to more accurately position the first heat dissipation member 2A to the first substrate 3A when attaching the first heat dissipation member 2A to the first substrate 3A after forming the first substrate 3A, the first semiconductor elements 10A, the second semiconductor elements 10B, and the sealing resin 8. This can reduce the labor required for manufacturing. Thus, it is possible to improve heat dissipation efficiency and save labor during the manufacturing process.

The first bases 21A and the first reverse-surface metal layer 33A, which are made of different metals, are joined by laser bonding, whereby the heat generated during the joining process can be reduced. This reduces the possibilities of unintended damage or the like to the first semiconductor elements 10A, the second semiconductor elements 10B, and the conductive paths of these semiconductor elements.

The first heat dissipation member 2A includes the first connecting portions 23A. As such, the first heat dissipation member 2A is configured with a plurality of water channels each having a rectangular shape as viewed in the second direction y. This further improves the heat dissipation efficiency of the electric power conversion unit B1.

The first bases 21A, the first upright portions 22A, and the first connecting portions 23A extend in the second direction y. As such, a plurality of flow channels are formed to extend across the first reverse surface 302A in the second direction y. The supply section 92 and the discharge section 93 of the cooling device 9 are disposed on the respective sides in the second direction y. This allows the cooling medium Cm to flow along the first heat dissipation member 2A in the second direction y, thus improving the heat dissipation efficiency of the semiconductor device A1.

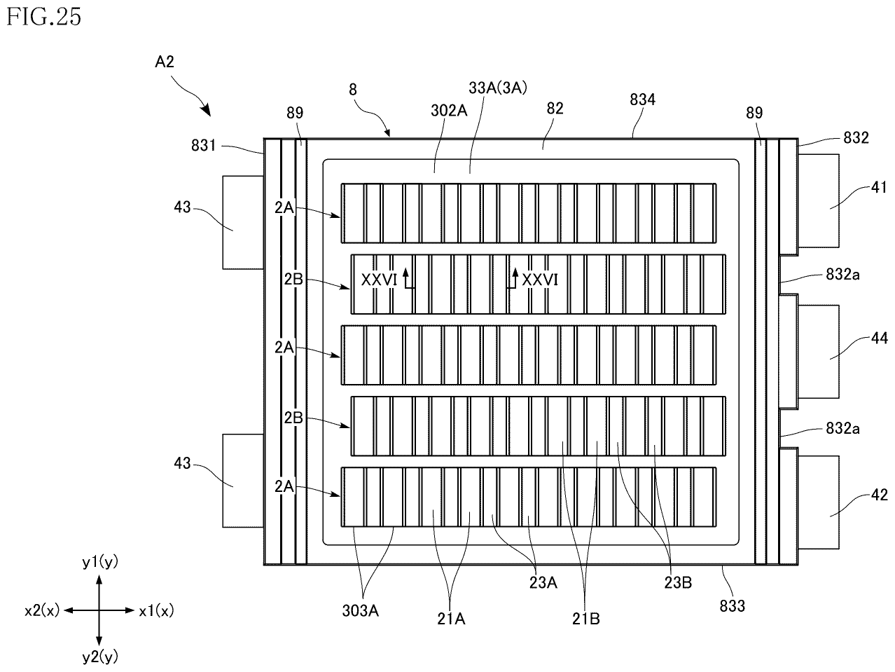

FIGS. 25 to 28 show other embodiments of the present disclosure. In these figures, elements that are the same as or similar to those in the above embodiment are provided with the same reference numerals as in the above embodiment. The configurations of the elements in each embodiment can be combined as appropriate as long as the combination does not cause technical inconsistency.

### Second Embodiment

FIGS. 25 to 27 show a heat dissipation member of a semiconductor device according to a second embodiment of the present disclosure. A semiconductor device A2 of the present embodiment is different from the above embodiment in that the semiconductor device A2 includes a plurality of first heat dissipation members 2A and a plurality of second heat dissipation members 2B, and in the configuration of the first substrate 3A.

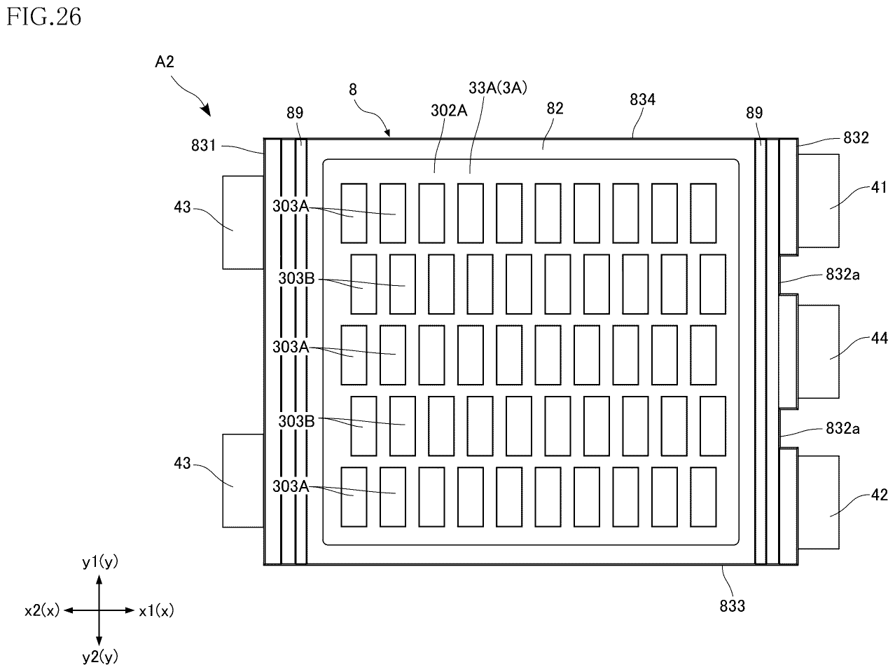

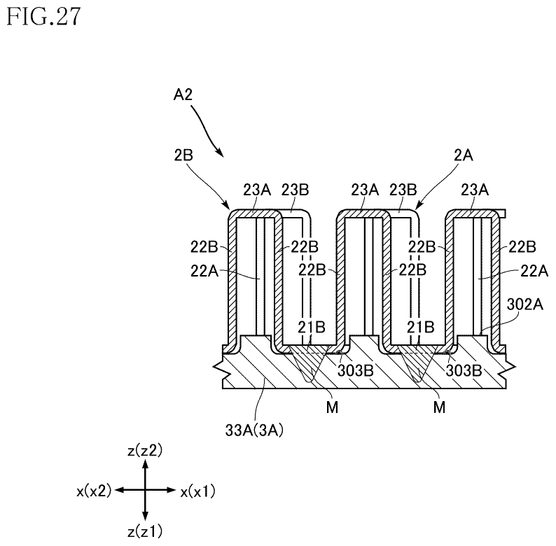

As shown in FIGS. 26 and 27, the first reverse-surface metal layer 33A of the present embodiment includes a plurality of first recesses 303A and a plurality of second recesses 303B.

The first recesses 303A and the second recesses 303B are recessed from the first reverse surface 302A to the z1 side in the thickness direction z. In the present embodiment, the first recesses 303A are aligned in the first direction x. The second recesses 303B are also aligned in the first direction x. The first recesses 303A and the second recesses 303B are alternately arranged in the second direction y. A first recess 303A and a second recess 303B adjacent in the second direction y are shifted in position in the first direction x. Although the first recesses 303A and the second recesses 303B of the present embodiment are rectangular as viewed in the thickness direction z, the shape of each of these recesses is not particularly limited.

The first heat dissipation members 2A and the second heat dissipation members 2B are disposed on the surface of the first substrate 3A (the first reverse-surface metal layer 33A) on the z2 side in the thickness direction z. The first heat dissipation members 2A and the second heat dissipation members 2B are alternately arranged in the second direction y. Each of the first heat dissipation members 2A may have the same configuration as the first heat dissipation member 2A in the semiconductor device A1 except that the first heat dissipation member 2A in the semiconductor device A2 is smaller in the second direction y than the first heat dissipation member 2A in the semiconductor device A1.

Each of the second heat dissipation members 2B has a plurality of second bases 21B, a plurality of second upright portions 22B, and a plurality of second connecting portions 23B. The material of the second heat dissipation members 2B is not particularly limited. For example, each of the second head dissipation members 2B is made of a metal plate material. The metal plate material may contain a metal such as copper (Cu), aluminum (Al), or stainless steel, or an alloy of these metals.

The second bases 21B are located on the z1 side in the thickness direction z. The second bases 21B are housed in the respective second recesses 303B. In the second recesses 303B, the second bases 21B are bonded to the first reverse-surface metal layer 33A. The method for bonding the second bases 21B to the first reverse-surface metal layer 33A is not particularly limited, and can be selected as appropriate from a welding method such as laser welding, a method using joints such as brazing, or other methods such as ultrasonic bonding or solid-phase diffusion bonding. In the illustrated example, the second bases 21B are bonded to the first reverse-surface metal layer 33A by laser bonding. In this case, parts of the second bases 21B and parts of the first reverse-surface metal layer 33A are melted and solidified to form welded portions M. In the present embodiment, the thickness of each second base 21B in the thickness direction z is smaller than the depth of each second recess 303B in the thickness direction z. The shape of each second base 21B is not particularly limited. In the present embodiment, each second base 21B has a strip shape extending in the second direction y. Each second base 21B may be sized and shaped to fit in a second recess 303B, or may be slightly smaller than a second recess 303B.

The second upright portions 22B are connected to the respective ends of the second bases 21B in the first direction x, and stand in the thickness direction z. The second upright portions 22B protrude beyond the first reverse surface 302A to the z2 side in the thickness direction z. In the present embodiment, the length of each second upright portion 22B in the second direction y is equal (or substantially equal) to the length of each second base 21B in the second direction y. Each of the second upright portions 22B has a strip shape extending in the second direction y, for example.

Each of the second connecting portions 23B connects the z2-side ends in the thickness direction z of second upright portions 22B adjacent to each other in the first direction x. In the present embodiment, the length of each second connecting portion 23B in the second direction y is equal (or substantially equal) to the length of each second upright portion 22B in the second direction y. The shape of each second connecting portion 23B as viewed in the thickness direction z is not particularly limited, and may be a strip shape in the present embodiment. The shape of each second connecting portion 23B as viewed in the second direction y is not particularly limited, and may be a flat shape along the first direction x as illustrated, or may be a dome shape or a ridge shape that bulges to the z2 side in the thickness direction z.

Since a first recess 303A and a second recess 303B adjacent in the second direction y are shifted in position in the first direction x, a first connecting portion 23A and a second connecting portion 23B adjacent in the second direction y are also shifted in position in the first direction x.

The present embodiment can also improve heat dissipation efficiency and save labor during the manufacturing process. The flow channels formed by the first heat dissipation members 2A are offset from the flow channels formed by the second heat dissipation members 2B in the first direction x. Thus, the cooling medium Cm is likely to meander when flowing from the supply section 92 to the discharge section 93 in the cooling device 9. This facilitates heat transfer from the first heat dissipation members 2A and the second heat dissipation members 2B, thereby further improving heat dissipation efficiency.

As can be understood from the present embodiment, the respective numbers of first heat dissipation members 2A and second heat dissipation members 2B are not particularly limited.

### Third Embodiment

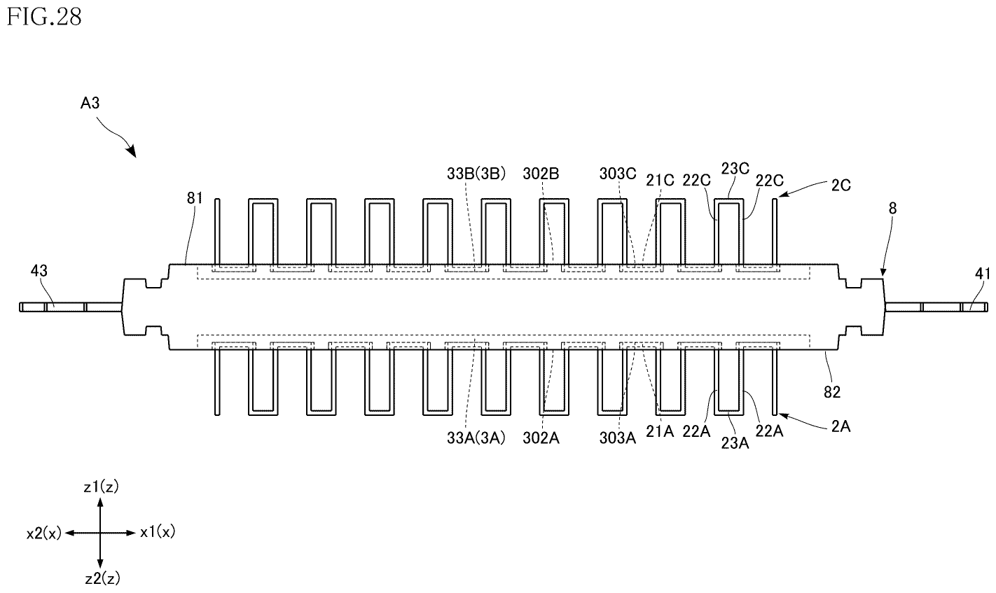

FIG. 28 shows a semiconductor device according to a third embodiment of the present disclosure. A semiconductor device A3 of the present embodiment is different from the above embodiments in that the semiconductor device A3 includes a first heat dissipation member 2A, a third heat dissipation member 2C, a first substrate 3A, and a second substrate 3B.

The second substrate 3B is disposed on the z1 side in the thickness direction z with respect to the first semiconductor elements 10A and the second semiconductor elements 10B. The specific configuration of the second substrate 3B is not particularly limited. For example, the second substrate 3B may be a direct bonded copper (DBC) substrate or an active metal brazing (AMB) substrate. The second substrate 3B may be directly bonded to at least either of the first semiconductor elements 10A and the second semiconductor elements 10B, or may be configured to transfer heat via a bonding layer (not illustrated) or a metal member (not illustrated).

In the illustrated example, the second substrate 3B has a second reverse-surface metal layer 33B. The second reverse-surface metal layer 33B is made of the same material as the first reverse-surface metal layer 33A described above. The second reverse-surface metal layer 33B has a second reverse surface 302B and a plurality of third recesses 303C.

The second reverse surface 302B faces the z1 side in the thickness direction z. The second reverse surface 302B is exposed from the sealing resin 8. The third recesses 303C are recessed from the second reverse surface 302B to the z2 side in the thickness direction z. In the present embodiment, the third recesses 303C are aligned in the first direction x. The specific shape of each third recess 303C is not particularly limited. For example, each third recess 303C may be a groove extending in the second direction y or may have a rectangular shape as viewed in the thickness direction z.

The third heat dissipation member 2C is disposed on the surface of the second substrate 3B (the second reverse-surface metal layer 33B) on the z1 side in the thickness direction z. The third heat dissipation member 2C has a plurality of third bases 21C, a plurality of third upright portions 22C, and a plurality of third connecting portions 23C. The material of the third heat dissipation member 2C is not particularly limited. For example, the third heat dissipation member 2C is made of a metal plate material. The metal plate material may contain a metal such as copper (Cu), aluminum (Al), or stainless steel, or an alloy of these metals.

The third bases 21C are located on the z2 side in the thickness direction z. The third bases 21C are housed in the respective third recesses 303C. In the third recesses 303C, the third bases 21C are bonded to the second reverse-surface metal layer 33B. The method for bonding the third bases 21C to the second reverse-surface metal layer 33B is not particularly limited, and can be selected as appropriate from a welding method such as laser welding, a method using joints such as brazing, or other methods such as ultrasonic bonding or solid-phase diffusion bonding. In the present embodiment, the thickness of each third base 21C in the thickness direction z is smaller than the depth of each third recess 303C in the thickness direction z. The shape of each third base 21C is not particularly limited. For example, each third base 21C has a strip shape extending in the second direction y. Each third base 21C may be sized and shaped to fit in a third recess 303C, or may be slightly smaller than a third recess 303C.

The third upright portions 22C are connected to the respective ends of the third bases 21C in the first direction x, and stand in the thickness direction z. The third upright portions 22C protrude beyond the second reverse surface 302B to the z1 side in the thickness direction z. In the present embodiment, the length of each third upright portion 22C in the second direction y is equal (or substantially equal) to the length of each third base 21C in the second direction y. The shape of each third upright portion 22C is not particularly limited. For example, each third upright portion 22C has a strip shape extending in the second direction y.

Each of the third connecting portions 23C connects the z1-side ends in the thickness direction z of third upright portions 22C adjacent to each other in the first direction x. In the present embodiment, the length of each third connecting portion 23C in the second direction y is equal (or substantially equal) to the length of each third upright portion 22C in the second direction y. The shape of each third connecting portion 23C as viewed in the thickness direction z is not particularly limited, and may be a strip shape in the present embodiment. The shape of each third connecting portion 23C as viewed in the second direction y is not particularly limited, and may be a flat shape along the first direction x as illustrated, or may be a dome shape or a ridge shape that bulges to the z1 side in the thickness direction z.

The present embodiment can also improve heat dissipation efficiency and save labor during the manufacturing process. In addition, the first heat dissipation member 2A and the third heat dissipation member 2C are disposed on the opposite sides in the thickness direction z to cool the semiconductor device A3 from both sides in the thickness direction z. This is advantageous for improving heat dissipation efficiency.

The semiconductor device, the electric power conversion unit, and the method for manufacturing the semiconductor device according to the present disclosure are not limited to the above embodiments. Various design changes can be made to the specific configurations of the semiconductor device, the electric power conversion unit, and the method for manufacturing the semiconductor device according to the present disclosure. The present disclosure includes the embodiments described in the following clauses.

Clause 1. A semiconductor device comprising:
a semiconductor element;
a first substrate supporting the semiconductor element;
a sealing resin covering the semiconductor element and a part of the first substrate; and
a first heat dissipation member,
wherein the first substrate includes an obverse surface facing a first side in a thickness direction, and a first reverse surface facing a second side in the thickness direction and exposed from the sealing resin,
the semiconductor element is mounted on the obverse surface,
the first heat dissipation member is disposed on a surface of the first substrate on the second side in the thickness direction,
the first heat dissipation member includes a plurality of first bases located on the first side in the thickness direction, and a plurality of first upright portions extending from the plurality of first bases to the second side in the thickness direction,
the first substrate includes a plurality of first recesses recessed from the first reverse surface to the first side in the thickness direction, and
the plurality of first bases are housed in the respective first recesses.

Clause 2. The semiconductor device according to clause 1, wherein the first substrate includes a first reverse-surface metal layer formed with the plurality of first recesses, and
the first heat dissipation member is bonded to the first reverse-surface metal layer.

Clause 3. The semiconductor device according to clause 2, wherein the first heat dissipation member is made of metal.

Clause 4. The semiconductor device according to clause 2 or 3, wherein the plurality of first recesses are aligned in a first direction perpendicular to the thickness direction.

Clause 5. The semiconductor device according to clause 4, wherein the plurality of first recesses are a plurality of grooves extending in a second direction perpendicular to the thickness direction and the first direction.

Clause 6. The semiconductor device according to clause 5, wherein the first heat dissipation member includes a first connecting portion that connects second-side ends of two first upright portions adjacent in the first direction out of the plurality of first upright portions, the second-side ends being ends of the adjacent first upright portions located on the second side in the thickness direction.

Clause 7. The semiconductor device according to clause 4, further comprising a second heat dissipation member disposed on the surface of the first substrate on the second side in the thickness direction,
wherein the second heat dissipation member includes a plurality of second bases located on the first side in the thickness direction, and a plurality of second upright portions extending from the second bases to the second side in the thickness direction,
the first substrate includes a plurality of second recesses recessed from the first reverse surface to the first side in the thickness direction,
the plurality of second bases are housed in the respective second recesses, and
the plurality of first recesses and the plurality of second recesses are adjacent to each other in a second direction perpendicular to the thickness direction and the first direction.

Clause 8. The semiconductor device according to clause 7, wherein the second heat dissipation member is bonded to the first reverse-surface metal layer.

Clause 9. The semiconductor device according to clause 8, wherein the second heat dissipation member is made of metal.

Clause 10. The semiconductor device according to clause 8 or 9, wherein the plurality of second recesses are aligned in the first direction.

Clause 11. The semiconductor device according to any of clauses 7 to 10, wherein the plurality of first recesses include a first recess that is adjacent to one of the plurality of second recesses in the second direction, and the first recess and the second recess, which are adjacent to each other in the second direction, are shifted in position in the first direction.

Clause 12. The semiconductor device according to any of clauses 2 to 11, wherein the first substrate includes a first insulating layer located on the first side in the thickness direction with respect to the first reverse-surface metal layer, and a first metal layer located on the first side in the thickness direction with respect to the first insulating layer.

Clause 13. The semiconductor device according to any of clauses 1 to 12, further comprising:
a second substrate located on the first side in the thickness direction with respect to the semiconductor element; and
a third heat dissipation member,
wherein the second substrate includes a second reverse surface facing the first side in the thickness direction and exposed from the sealing resin,
the third heat dissipation member is disposed on a surface of the second substrate on the first side in the thickness direction,
the third heat dissipation member includes a plurality of third bases located on the second side in the thickness direction, and a plurality of third upright portions extending from the third bases to the first side in the thickness direction,
the second substrate includes a plurality of third recesses recessed from the second reverse surface to the second side in the thickness direction, and
the plurality of third bases are housed in the respective third recesses.

Clause 14. The semiconductor device according to clause 13, wherein the second substrate includes a second reverse-surface metal layer formed with the plurality of third recesses, and
the third heat dissipation member is bonded to the second reverse-surface metal layer.

Clause 15. The semiconductor device according to clause 14, wherein the third heat dissipation member is made of metal.

Clause 16. The semiconductor device according to clause 14 or 15, wherein the plurality of third recesses are aligned in the first direction perpendicular to the thickness direction.

Clause 17. An electric power conversion unit comprising:
the semiconductor device according to any of clauses 1 to 16, and
a cooling device disposed on the second side in the thickness direction with respect to the semiconductor device, and
wherein the cooling device includes a housing that houses the first heat dissipation member, and that allows a cooling medium to flow.

### REFERENCE NUMERALS

A1, A2, A3: Semiconductor device
B1: Electric power conversion unit
2A: First heat dissipation member
2B: Second heat dissipation member
2C: Third heat dissipation member
3: Support substrate
3A: First substrate
3B: Second substrate
5: First conductive member
6: Second conductive member
8: Sealing resin
9: Cooling device
10A: First semiconductor element
10B: Second semiconductor element
11: First obverse-surface electrode
12: Second obverse-surface electrode
13: Third obverse-surface electrode
15: Reverse-surface electrode
17: Thermistor
19A: First conductive bonding member
19B: Second conductive bonding member
21A: First base
21B: Second base
21C: Third base
22A: First upright portion
22B: Second upright portion
22C: Third upright portion
23A: First connecting portion
23B: Second connecting portion
31A: First insulating layer
32A: First obverse-surface metal layer
33A: First reverse-surface metal layer
33B: second reverse-surface metal layer
41: First terminal
42: Second terminal
43: Third terminal
44: Fourth terminal
45: Control terminal
46A-46E: First control terminal
47A-47D: Second control terminal
48: Control terminal support
48A: First support portion
48B: Second support portion
49: Bonding member
51: Main portion
52: First bonding portion
53: Second bonding portion
59: Conductive bonding member
61: Third bonding portion
64: First path portion
65: Second path portion
66: Third path portion
67: Fourth path portion
69: Conductive bonding member
71-74: Wire
81: Resin obverse surface
82: Resin reverse surface
86: Resin cavity
89: Groove
91: Housing
92: Supply section
93: Discharge section
101: Element obverse surface
102: Element reverse surface
121: Gate finger
301A: First obverse surface
301B: Second obverse surface
302A: First reverse surface
302B: Second reverse surface
303A: First recess
303B: Second recess
303C: Third recess
321: First conductive portion
322: Second conductive portion
451: Holder
452: Metal pin
459: Conductive bonding member
481: Insulating layer
482: First metal layer
482A: First region
482B: Second region
482C: Third region
482D: Fourth region
482E: Fifth region
482F: Sixth region
483: Second metal layer
514: First opening
602: First ramp portion
603: Second ramp portion
611: Flat section
612: First inclined section
641: First band-shaped section
643: First extended section
649: Recess
651: Second band-shaped section
653: Second extended section
659, 669: Recess
831-834: Resin side surface
832a: Recess
851: First protrusion
851a: First protrusion end surface
851b: Recess
851c: Inner wall surface
852: Second protrusion
911: Groove
919: Sealant
Cm: Cooling medium
M: Welded portion
x: First direction
y: Second direction
z: Thickness direction

1. A semiconductor device comprising:
a semiconductor element;
a first substrate supporting the semiconductor element;
a sealing resin covering the semiconductor element and a part of the first substrate; and
a first heat dissipation member,
wherein the first substrate includes an obverse surface facing a first side in a thickness direction, and a first reverse surface facing a second side in the thickness direction and exposed from the sealing resin,
the semiconductor element is mounted on the obverse surface,
the first heat dissipation member is disposed on a surface of the first substrate on the second side in the thickness direction,
the first heat dissipation member includes a plurality of first bases located on the first side in the thickness direction, and a plurality of first upright portions extending from the plurality of first bases to the second side in the thickness direction,
the first substrate includes a plurality of first recesses recessed from the first reverse surface to the first side in the thickness direction, and
the plurality of first bases are housed in the respective first recesses.

2. The semiconductor device according to claim 1, wherein the first substrate includes a first reverse-surface metal layer formed with the plurality of first recesses, and
the first heat dissipation member is bonded to the first reverse-surface metal layer.

3. The semiconductor device according to claim 2, wherein the first heat dissipation member is made of metal.

4. The semiconductor device according to claim 2, wherein the plurality of first recesses are aligned in a first direction perpendicular to the thickness direction.

5. The semiconductor device according to claim 4, wherein the plurality of first recesses are a plurality of grooves extending in a second direction perpendicular to the thickness direction and the first direction.

6. The semiconductor device according to claim 5, wherein the first heat dissipation member includes a first connecting portion that connects second-side ends of two first upright portions adjacent in the first direction out of the plurality of first upright portions, the second-side ends being ends of the adjacent first upright portions located on the second side in the thickness direction.

7. The semiconductor device according to claim 4, further comprising a second heat dissipation member disposed on a surface of the first substrate on the second side in the thickness direction,
wherein the second heat dissipation member includes a plurality of second bases located on the first side in the thickness direction, and a plurality of second upright portions extending from the second bases to the second side in the thickness direction,
the first substrate includes a plurality of second recesses recessed from the first reverse surface to the first side in the thickness direction,
the plurality of second bases are housed in the respective second recesses, and
the plurality of first recesses and the plurality of second recesses are adjacent to each other in a second direction perpendicular to the thickness direction and the first direction.

8. The semiconductor device according to claim 7, wherein the second heat dissipation member is bonded to the first reverse-surface metal layer.

9. The semiconductor device according to claim 8, wherein the second heat dissipation member is made of metal.

10. The semiconductor device according to claim 8, wherein the plurality of second recesses are aligned in the first direction.

11. The semiconductor device according to claim 7, wherein the plurality of first recesses include a first recess that is adjacent to one of the plurality of second recesses in the second direction, and the first recess and the second recess, which are adjacent to each other in the second direction, are shifted in position in the first direction.

12. The semiconductor device according to claim 2, wherein the first substrate includes a first insulating layer located on the first side in the thickness direction with respect to the first reverse-surface metal layer, and a first metal layer located on the first side in the thickness direction with respect to the first insulating layer.

13. The semiconductor device according to claim 1, further comprising: a second substrate located on the first side in the thickness direction with respect to the semiconductor element; and
a third heat dissipation member,
wherein the second substrate includes a second reverse surface facing the first side in the thickness direction and exposed from the sealing resin,
the third heat dissipation member is disposed on a surface of the second substrate on the first side in the thickness direction,
the third heat dissipation member includes a plurality of third bases located on the second side in the thickness direction, and a plurality of third upright portions extending from the third bases to the first side in the thickness direction,
the second substrate includes a plurality of third recesses recessed from the second reverse surface to the second side in the thickness direction, and
the plurality of third bases are housed in the respective third recesses.

14. The semiconductor device according to claim 13, wherein the second substrate includes a second reverse-surface metal layer formed with the plurality of third recesses, and
the third heat dissipation member is bonded to the second reverse-surface metal layer.

15. The semiconductor device according to claim 14, wherein the third heat dissipation member is made of metal.

16. The semiconductor device according to claim 14, wherein the plurality of third recesses are aligned in the first direction perpendicular to the thickness direction.

17. An electric power conversion unit comprising: the semiconductor device according to claim 1, and
a cooling device disposed on the second side in the thickness direction with respect to the semiconductor device, and
wherein the cooling device includes a housing that houses the first heat dissipation member, and that allows a cooling medium to flow.
